(19) United States
(12) Patent Application Publication
(10) Pub. No.: US 2017/0012022 A1
(43) Pub. Date: Jan. 12, 2017

(54) PHOTOSENSITIVE RESIN COMPOSITION, LAMINATE, METHOD FOR MANUFACTURING SEMICONDUCTOR DEVICE, AND SEMICONDUCTOR DEVICE

(71) Applicant: FUJIFILM Corporation, Tokyo (JP)

(72) Inventors: Kenta YOSHIDA, Haibara-gun (JP); Yu IWAI, Haibara-gun (JP)

(73) Assignee: FUJIFILM Corporation, Tokyo (JP)

(21) Appl. No.: 15/275,787

(22) Filed: Sep. 26, 2016

Related U.S. Application Data
(63) Continuation of application No. PCT/JP2015/059047, filed on Mar. 25, 2015.

(30) Foreign Application Priority Data
Mar. 28, 2014 (JP) 2014-069007

(51) Int. Cl. H01L 23/00; C08G 73/12; C08G 73/10; G03F 7/031; G03F 7/20; C09J 179/08; G03F 7/16; H01L 25/00; C09J 7/02; C09J 5/02; C09J 5/06; G03F 7/037; G03F 7/32

(52) U.S. Cl. CPC H01L 24/83; G03F 7/037; C08G 73/128; C08G 73/106; G03F 7/031; H01L 24/27; G03F 7/20; G03F 7/322; G03F 7/162; H01L 24/29; H01L 24/30; H01L 25/50; C09J 7/026; C09J 5/02; C09J 5/06; C09J 179/085; C09J 179/08; H01L 2224/83031; H01L 2224/83191; H01L 2224/83862; H01L 2224/2731; H01L 2224/27515; H01L 2224/27622; H01L 2224/2957; H01L 2224/2969

(57) ABSTRACT

There are provided a photosensitive resin composition having excellent heat resistance, developability, and curability, a laminate obtained by using a photosensitive resin composition, a method for manufacturing a semiconductor device, and a semiconductor device.

The photosensitive resin composition includes a polymer including a repeating unit derived from an acid group-containing maleimide, a crosslinking agent, a photopolymerization initiator, and a thermal polymerization initiator. The polymer preferably further includes a repeating unit derived from a vinyl compound.

### CROSS-REFERENCE TO RELATED APPLICATIONS

This application is a Continuation of PCT International Application No. PCT/JP2015/059047 filed on Mar. 25, 2015, which claims priority under 35 U.S.C §119(a) to Japanese Patent Application No. 2014-069007 filed on Mar. 28, 2014. Each of the above application(s) is hereby expressly incorporated by reference, in its entirety, into the present application.

### BACKGROUND OF THE INVENTION

1. Field of the Invention

The present invention relates to a photosensitive resin composition, a laminate, a method for manufacturing a semiconductor device, and a semiconductor device. More specifically, the present invention relates to a photosensitive resin composition which can be suitably used as an underfill, a laminate, a method for manufacturing a semiconductor device, and a semiconductor device.

2. Description of the Related Art

In manufacture of semiconductor devices, at the time of bonding between semiconductor elements or connection between a semiconductor element and a semiconductor wafer, an underfill is used.

In addition, with the need for further miniaturization and performance enhancement of electronic apparatuses, there has been demand for further miniaturization and higher integration of IC chips to be mounted on an electronic apparatus.

For this reason, even in a 2.5-dimensional mounting device or a 3-dimensional mounting device, it is required to decrease an electrode pitch on a semiconductor element and narrow a distance between chips.

As a sealing method with an underfill, a method of bonding an electrode to a semiconductor element and then sealing the gap between semiconductor elements by filling the gap between the semiconductor elements with an underfill has been performed in the related art (hereinafter, also referred to as a post-attachment underfill sealing method).

However, in the case of the post-attachment underfill sealing method, when decreasing the electrode pitch or narrowing the distance between chips between the semiconductor elements, there is a tendency that filling with an underfill becomes difficult, and there is a concern that the reliability of bonding may decrease.

In addition, a technique in which, before connecting an electrode between semiconductor elements, by supplying an underfill on the surface of one semiconductor element and bonding an electrode by pressing the other semiconductor element, adhesion with an underfill is performed is known (hereinafter, also referred to as a pre-attachment underfill sealing method).

At this time, by the underfill on the electrode being pushed out to the surroundings at the time of pressure bonding or only the underfill on the electrode being removed in pattern exposure and developing step, conduction between the electrodes of the semiconductor elements can be ensured.

As the underfill used in the pre-attachment underfill sealing method, for example, compositions including a polyimide resin (JP2010-006983A or WO2011/001942A) and compositions including an epoxy resin (JP2009-256588A) are known.

In JP2010-126542A, a UV curable resin composition including an acrylic resin is disclosed.

In WO2009/090922A, it is disclosed that a photosensitive adhesive composition including a polyimide resin having a carboxyl group is used in an underfill or the like.

In addition, in JP2009-242771A, a photosensitive adhesive composition for a semiconductor element including an alkali-soluble polymer which is a copolymer including a monomer unit derived from a maleimide monomer having a maleimide group and a monomer unit derived from a monofunctional vinyl monomer, a thermosetting resin, a radiation polymerizable compound, and a photoinitiator is disclosed.

### SUMMARY OF THE INVENTION

However, in the photosensitive resin composition using a polyimide resin or an epoxy resin as described in JP2010-006983A, WO2011/001942A, JP2009-256588A, or WO2009/090922A, developability is not sufficient. It is found that these resins have a high curing temperature, and thus, these resins thermally damage a device during adhering in some cases. In addition, since these resins have a long curing time, the productivity of semiconductor devices tends to decrease.

On the other hand, it is found that, in a photosensitive resin composition using an acrylic resin as described in JP2010-126542A, the heat resistance of the resin is low, and thus, the resin does not endure the high temperature generated at the time of electrode bonding, and the reliability of bonding decreases.

In addition, when the present inventors examined the photosensitive adhesive composition for a semiconductor element disclosed in JP2009-242771A, it was found that the curability is not sufficient.

Accordingly, an object of the present invention is to provide a photosensitive resin composition having excellent heat resistance, developability, and curability, a laminate obtained by using the photosensitive resin composition, a method for manufacturing a semiconductor device, and a semiconductor device.

As a result of thorough examination, the present inventors found that, by using a polymer including a repeating unit derived from an acid group-containing maleimide, a crosslinking agent, a photopolymerization initiator, and a thermal polymerization initiator in combination, it is possible to provide a photosensitive resin composition capable of forming a pattern having excellent heat resistance and developability, and completed the present invention. Specifically, the above-described problem was solved by the following means <1>, and preferably by <2> to <18>.

<1> A photosensitive resin composition comprising a polymer including a repeating unit derived from an acid group-containing maleimide, a crosslinking agent, a photopolymerization initiator, and a thermal polymerization initiator.

<2> The photosensitive resin composition according to <1>, in which the polymer further includes a repeating unit derived from a vinyl compound.

<3> The photosensitive resin composition according to <1> or <2>, further comprising a solvent.

<4> The photosensitive resin composition according to any one of <1> to <3>, in which the crosslinking agent is a compound having two or more groups having an ethylenically unsaturated bond.

<5> The photosensitive resin composition according to any one of <1> to <4>, in which the crosslinking agent has a partial structure represented by the following formulas; here, * in the formulas is a linking arm.

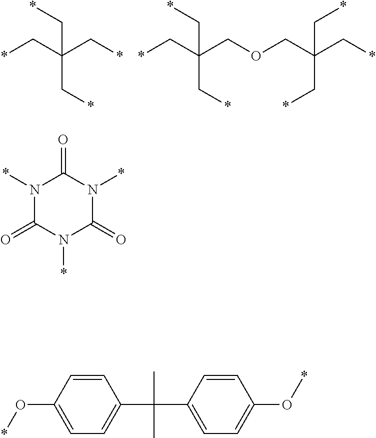

<6> The photosensitive resin composition according to any one of <1> to <5>, in which the polymer is a polymer including a repeating unit represented by the following General Formula (1) and a repeating unit represented by the following General Formula (2).

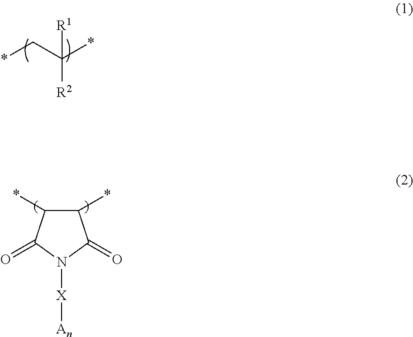

In General Formulas (1) and (2), R¹ represents a hydrogen atom or a methyl group, R² represents a hydrogen atom, an alkyl group, an alkoxy group, or an aryl group, X represents an n+1 valent linking group, A represents an acid group, n represents an integer of 1 to 10, and * represents a linking arm.

<7> The photosensitive resin composition according to any one of <1> to <6>, in which the acid value of the polymer is 50 mgKOH/g or greater.

<8> The photosensitive resin composition according to any one of <1> to <7>, in which the weight loss ratio of the polymer at 300° C. when the temperature is raised at a rate of 20° C./min is 5% or less.

<9> The photosensitive resin composition according to any one of <1> to <8>, further comprising a filler.

<10> The photosensitive resin composition according to any one of <1> to <9>, further comprising an adhesiveness-imparting agent.

<11> The photosensitive resin composition according to any one of <1> to <10>, which is for an underfill.

<12> The photosensitive resin composition according to any one of <1> to <11>, which is liquid.

<13> The photosensitive resin composition according to any one of <1> to <11>, which has a sheet-shape.

<14> A laminate, comprising a layer formed of the photosensitive resin composition according to any one of <1> to <13> on a semiconductor wafer surface.

<15> A laminate, comprising a cured product layer formed by curing the photosensitive resin composition according to any one of <1> to <13> on a semiconductor wafer surface.

<16> A manufacturing method for a semiconductor device, comprising a step of applying a photosensitive resin composition according to <12> to a semiconductor wafer, a step of drying the photosensitive resin composition applied to the semiconductor wafer, a step of exposing the dried photosensitive resin composition, a step of developing the exposed photosensitive resin composition, and a step of thermal-pressing the adherend against a surface of the developed photosensitive resin composition.

<17> A manufacturing method for a semiconductor device, comprising a step of laminating the photosensitive resin composition according to <13> on a semiconductor wafer, a step of exposing the photosensitive resin composition laminated on the semiconductor wafer, a step of developing the exposed photosensitive resin composition, and a step of thermal-pressing the adherend against a surface of the developed photosensitive resin composition.

<18> A semiconductor device manufactured by the method according to <16> or <17>.

It is possible to provide a photosensitive resin composition having excellent heat resistance, developability, and curability, a cured film obtained by using the photosensitive resin composition, a method for manufacturing a cured film, and a semiconductor device.

### BRIEF DESCRIPTION OF THE DRAWINGS

FIG. 1 is a schematic sectional view showing one embodiment of a sheet-shaped photosensitive resin composition.

FIG. 2 is a schematic sectional view showing one embodiment of an adhesive sheet.

FIG. 3 is a schematic sectional view showing another embodiment of the adhesive sheet.

FIG. 4 is a schematic sectional view showing another embodiment of the adhesive sheet.

FIG. 5 is a top view showing one embodiment of a semiconductor wafer provided with an adhesive layer.

FIG. 6 is an end view taken along a line VI-VI of FIG. 5.

FIG. 7 is a top view showing one embodiment of an adhesive layer pattern.

FIG. 8 is an end view taken along a line VII-VII of FIG. 7.

FIG. 9 is a top view showing one embodiment of the adhesive layer pattern.

FIG. 10 is an end view taken along a line X-X of FIG. 9.

FIG. 11 is a schematic sectional view showing one embodiment of a semiconductor device of the present invention.

FIG. 12 is a schematic sectional view showing another embodiment of the semiconductor device of the present invention.

FIG. 13 is a schematic sectional view showing another embodiment of the semiconductor device of the present invention.

### DESCRIPTION OF THE PREFERRED EMBODIMENTS

The description of the configuration elements in the present invention as described below is based on representative embodiments of the present invention, but the present invention is not limited to such embodiments.

Regarding the description of a group (atomic group) in the present specification, when the description does not indicate whether a group is substituted or unsubstituted, the description includes both the group having a substituent and the group not having a substituent. For example, “alkyl group” includes not only an alkyl group (an unsubstituted alkyl group) which does not have a substituent but also an alkyl group (a substituted alkyl group) which has a substituent.

The term “active light” in the present specification refers to, for example, a bright line spectrum of a mercury lamp, far-ultraviolet rays represented by an excimer laser, extreme ultraviolet rays (EUV light), X-rays, an electron beam, and the like. The light in the present invention refers to active light or radiation. The term “exposure” in the present specification includes not only the exposure performed using a mercury lamp, far-ultraviolet rays represented by an excimer laser, X-rays, or EUV light, but also drawing performed using a particle beam such as an electron beam, an ion beam, or the like, unless otherwise specified.

In the specification, ranges with the numerical values indicated by “to” mean the ranges including the numerical values described before and after the “to” as the upper limit and the lower limit, respectively.

In the present specification, “(meth)acrylate” represents either or both of acrylate and methacrylate, “(meth)acryl” represents either or both of acryl and methacryl, and “(meth)acryloyl” represents either or both of acryloyl and methacryloyl.

In the present specification, the term “step” includes not only an independent step, but also a step that is not clearly distinguished from other steps, as long as a desired action of the step is achieved.

The concentration of solid contents in the present specification is a percentage in terms of weight of the weight of other components excluding the solvent with respect to the total weight of the composition. The concentration of solid contents refers to a concentration at 25° C. unless otherwise stated.

In the present specification, the weight average molecular weight is defined as a value in terms of polystyrene measured by GPC. In the present specification, the weight average molecular weight (Mw) and the number average molecular weight (Mn) can be obtained, for example, by using an HLC-8220 (manufactured by TOSOH CORPORATION) and a TSK gel Super AWM-H (manufactured by TOSOH CORPORATION, 6.0 mm ID×15.0 cm) as a column. Measurement is performed using a 10 mmol/L lithium bromide NMP (N-methylpyrrolidinone) solution as an eluent, unless otherwise stated.

<Photosensitive Resin Composition>

The photosensitive resin composition of the present invention includes a polymer including a repeating unit derived from an acid group-containing maleimide, a crosslinking agent, a photopolymerization initiator, and a thermal polymerization initiator.

Since the photosensitive resin composition of the present invention includes a polymer including a repeating unit derived from an acid group-containing maleimide, it is possible to form a cured product having excellent heat resistance. In addition, since the maleimide contains an acid group, it is possible to form a pattern having excellent developability. In particular, in a case where a polymer includes maleimide and an acid group in the same repeating unit, the heat resistance is improved. In addition, since the photosensitive resin composition of the present invention includes a photopolymerization initiator and a thermal polymerization initiator, a polymerization reaction of the polymerizable compound proceeds efficiently, and the curability thereof is excellent.

Hereinafter, the present invention will be described in detail.

<Polymer Including Repeating Unit Derived from Acid Group-Containing Maleimide>

The photosensitive resin composition of the present invention includes a polymer (hereinafter, also referred to as a maleimide-based polymer) including a repeating unit derived from an acid group-containing maleimide.

The maleimide-based polymer used in the present invention preferably further contains a repeating unit derived from a vinyl compound. Among these, a polymer including a repeating unit represented by the following General Formula (1) and a repeating unit represented by the following General Formula (2) is preferable.

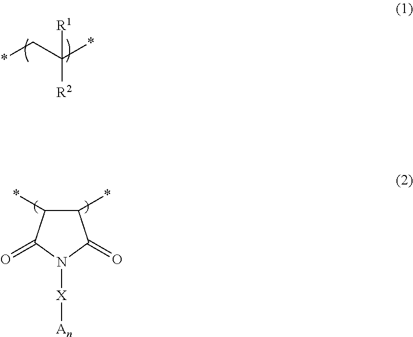

In General Formulas (1) and (2), R¹ represents a hydrogen atom or a methyl group, R² represents a hydrogen atom, an alkyl group, an alkoxy group, or an aryl group, X represents an n+1 valent linking group, A represents an acid group, n represents an integer of 1 to 10, and * represents a linking arm.

In General Formula (1), R¹ represents a hydrogen atom or a methyl group, and preferably a hydrogen atom.

In General Formula (1), R² represents a hydrogen atom, an alkyl group, an alkoxy group, or an aryl group.

As the alkyl group, an alkyl group having 1 to 30 carbon atoms is preferable, and an alkyl group having 1 to 20 carbon atoms is more preferable. The alkyl group may have any one of a linear chain shape, a branched chain shape, and a cyclic chain shape.

As the alkoxy group, an alkoxy group having 1 to 30 carbon atoms is preferable, and an alkoxy group having 1 to 20 carbon atoms is more preferable. The alkoxy group may have any one of a linear chain shape, a branched chain shape, and a cyclic chain shape.

As the aryl group, an aryl group having 6 to 30 carbon atoms is preferable, an aryl group having 6 to 20 carbon atoms is more preferable, and a phenyl group is particularly preferable.

R² in General Formula (1) is preferably a hydrogen atom or a phenyl group, and particularly preferably a phenyl group. In a case where R² is a hydrogen atom or a phenyl group, the heat resistance is further improved. In particular, in a case where R² is a phenyl group, the heat resistance is particularly improved.

In Formula (2), X represents an n+1 valent linking group. As the n+1 valent linking group, an aliphatic hydrocarbon group, an aromatic hydrocarbon group, a structure represented by —O— or —NR′— (R′ represents a hydrogen atom or an alkyl group which may have a substituent or an aryl group which may have a substituent, and a hydrogen atom is preferable), and a group including at least one selected from the group consisting of —SO₂—, —CO—, —O—, and —S— are exemplified. Among these, from the viewpoint of heat resistance, an aromatic hydrocarbon group is preferable.

For example, as the divalent linking group, an alkylene group, an arylene group, a structure represented by —O— or —NR′— (R′ represents a hydrogen atom or an alkyl group which may have a substituent or an aryl group which may have a substituent, and a hydrogen atom is preferable), and a group including at least one selected from the group consisting of —SO₂—, —CO—, —O—, and —S— are exemplified.

As the alkylene group, an alkylene group having 2 to 20 carbon atoms is preferable, and an alkylene group having 2 to 10 carbon atoms is more preferable.

As the arylene group, an arylene group having 6 to 30 carbon atoms is preferable, and an arylene group having 6 to 20 carbon atoms is more preferable.

As the divalent linking group, a phenylene group is particularly preferable.

Examples of the trivalent linking group include groups obtained by removing one hydrogen atom, from the linking groups exemplified as the divalent linking group. For example, a 3-substituted benzene ring is exemplified.

In General formula (2), A represents an acidic group, and from the viewpoint of alkali developability, a carboxyl group, a phosphonate group, a phosphate group, a sulfonate group, a hydroxyl group, or a sulfonamide group is preferable, and from the point of view of developability, a sulfonamide group or a carboxyl group is more preferable, and a carboxyl group is particularly preferable.

n represents an integer of 1 to 10, is preferably 1 to 5, and more preferably 1 or 2.

In the maleimide-based polymer used in the present invention, the ratio between the repeating unit represented by General Formula (1) and the repeating unit represented by General Formula (2) is preferably 1:1 to 6:1, more preferably 1:1 to 4:1, and still more preferably 1:1 to 3:1 in a molar ratio.

The maleimide-based polymer used in the present invention may include repeating units (hereinafter, also referred to as other repeating units) other than the repeating unit represented by General Formula (1) and the repeating unit represented by General Formula (2).

Examples of other repeating units include unsaturated carboxylic acids (for example, acrylic acid, methacrylic acid, itaconic acid, crotonic acid, isocrotonic acid, and maleic acid), an ester of an unsaturated carboxylic acid and an alcohol compound, an amide of an unsaturated carboxylic acid and an amine compound, and a repeating unit derived from an unsaturated carboxylic acid anhydride.

The content of other repeating units in all repeating units is preferably 10 mol % or less, more preferably 5 mol % or less, and particularly preferably, other repeating units are substantially not contained. Substantially not containing, for example, means that the content of other repeating units in all repeating units is preferably 1 mol % or less, more preferably 0.5 mol % or less, and other repeating units are particularly preferably not contained.

Hereinafter, specific examples of the maleimide-based polymer including the repeating unit represented by General Formula (1) and the repeating unit represented by General Formula (2) are described, but the present invention is not limited thereto. These can be used alone or in a mixture of two or more types thereof. Moreover, Me in the following formula represents a methyl group.

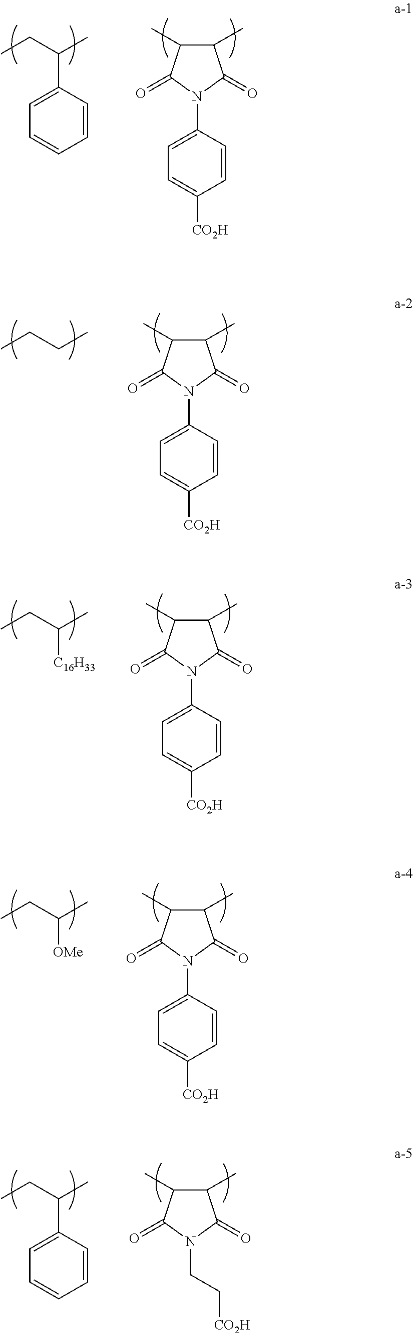

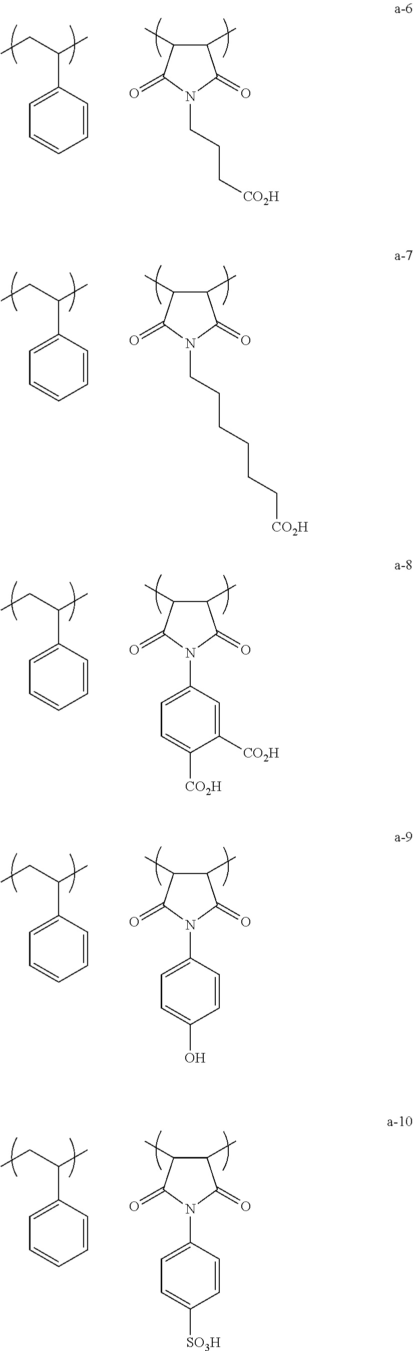

The above-described polymer including the repeating unit represented by General Formula (1) and the repeating unit represented by General Formula (2) can be synthesized by copolymerizing a vinyl compound and an acidic group-containing maleimide.

For example, the polymer can be obtained by radically copolymerizing a vinyl compound and an acidic group-containing maleimide. That is, the polymer can be synthesized by mixing a vinyl compound and an acidic group-containing maleimide in an arbitrary ratio in an organic solvent, adding a radical polymerization initiator or a chain transfer agent as necessary, and allowing to react.

In addition, the acidic group-containing maleimide can be obtained, for example, by imidizing using maleic acid anhydride and an acidic group-containing amine compound.

As another synthetic method, the acidic group-containing maleimide can also be obtained by radically copolymerizing a vinyl compound and maleic acid anhydride and then imidizing using an amine compound. At this time, as necessary, synthesis can also be performed by adding a base, an acid, or an acid anhydride.

The vinyl compound is not particularly limited as long as it is a compound having a group having an ethylenically unsaturated bond, and for example, an α-olefin compound, a conjugated diene compound, an aromatic vinyl compound, a vinyl ether compound, a vinyl ester compound, a (meth)acrylate compound, or a (meth)acrylamide compound is preferably used. Among these, from the viewpoint of the heat resistance of a copolymer, an α-olefin compound or an aromatic vinyl compound is preferably used, and an aromatic vinyl compound is more preferably used.

As the α-olefin, an α-olefin having 2 to 30 carbon atoms is preferable, and examples thereof include ethylene, propylene, 1-butene, 1-hexene, 1-octene, 1-decene, 1-dodecene, and 1-octadecene. Among these, ethylene is preferably used.

Examples of the aromatic vinyl compound include a styrene, an alkyl styrene, an aryl styrene, a halogenated styrene, an alkoxy styrene, and vinyl benzoic acid ester. Among these, styrene is preferably used.

Specific examples of the alkyl styrene include o-methyl styrene, m-methyl styrene, p-methyl styrene, o-ethyl styrene, m-ethyl styrene, p-ethyl styrene, o-n-propyl styrene, m-n-propyl styrene, p-n-propyl styrene, o-isopropyl styrene, m-isopropyl styrene, p-isopropyl styrene, m-n-butyl styrene, p-n-butyl styrene, p-tert-butyl styrene, 4-butenyl styrene, 2,4-dimethyl styrene, 2,5-dimethyl styrene, 3,5-dimethyl styrene, and mesityl styrene.

Specific examples of aryl styrene include p-phenyl styrene.

Specific examples of the halogenated styrene include o-fluorostyrene, m-fluorostyrene, p-fluorostyrene, o-chlorostyrene, m-chlorostyrene, p-chlorostyrene, o-bromostyrene, m-bromostyrene, and p-bromostyrene, o-methyl-p-fluorostyrene.

Specific examples of the alkoxy styrene include o-methoxystyrene, m-methoxystyrene, and p-methoxystyrene.

As the acidic group-containing maleimide, a compound having a structure represented by General Formula (2a) can be used.

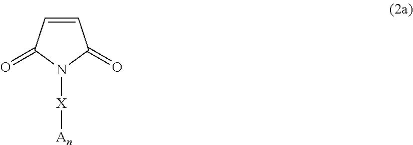

In General Formula (2a), X represents an n+1 valent linking group, A represents an acidic group, n represents an integer of 1 to 10.

X, A, and n in General Formula (2a) each have the same meaning as X, A, and n in General Formula (2), and the preferable ranges thereof are also the same.

The acid value of the maleimide-based polymer is preferably 50 mgKOH/g or greater, more preferably 80 to 300 mgKOH/g, and particularly preferably 100 to 250 mgKOH/g, from the viewpoint of developability. If the acid value is within the above range, the effects of the present invention are more effectively exhibited.

The weight loss ratio of the maleimide-based polymer at 300° C. when the temperature is raised at a rate of 20° C./min is preferably 5% or less, more preferably 3% or less, and particularly preferably 1% or less. If the weight loss ratio is within the above range, the heat resistance is further improved.

The weight-average molecular weight of the maleimide-based polymer is preferably 2,000 to 1,000,000, more preferably 3,000 to 500,000, and still more preferably 5,000 to 100,000, in terms of polystyrene by gel permeation chromatography (GPC). If the weight-average molecular weight is 2,000 or greater, heat resistance is improved, and if the weight-average molecular weight is 1,000,000 or less, developability is further improved.

The content of the maleimide-based polymer in the photosensitive resin composition of the present invention is preferably 30% to 90% by mass, more preferably 40% to 90% by mass, and particularly preferably 50% to 90% a by mass, with respect to the total solid content in the photosensitive resin composition.

<Crosslinking Agent>

The photosensitive resin composition of the present invention contains a crosslinking agent.

The crosslinking agent is a compound having two or more polymerizable groups, and as the crosslinking agent, known compounds polymerizable by the action of active light, radiation, light, heat, radicals, or an acid can be used. Such compounds are widely known in the industrial fields, and can be used without any particular limitation in the present invention. These may have any one of chemical forms such as a monomer, a prepolymer, an oligomer, a mixture thereof, or a multimer thereof.

The crosslinking agent in the present invention is a compound different from the maleimide-based polymer described above. That is, The crosslinking agent of the present invention is a compound not including a repeating unit derived from an acid group-containing maleimide.

In the present invention, the monomer type crosslinking agent (hereinafter, also referred to as a polymerizable monomer) is a compound different from the polymer compound. The polymerizable monomer is typically a low molecular weight compound, and is preferably a low molecular weight compound having a molecular weight of 2000 or less, more preferably a low molecular weight compound having a molecular weight of 1500 or less, and still more preferably a low molecular weight compound having a molecular weight of 900 or less. Moreover, the molecular weight of the polymerizable monomer is typically 100 or greater.

For example, the polymerizable group is preferably a functional group in which an addition polymerization reaction can proceed. Examples of the functional group in which an addition polymerization reaction can proceed include a group having an ethylenically unsaturated bond, an amino group, and an epoxy group. In addition, the polymerizable group may be a functional group which can generate radicals by light irradiation, and examples of such a polymerizable group include a thiol group and a halogen group. Among these, the polymerizable group is preferably a group having an ethylenically unsaturated bond. As the ethylenically unsaturated bond group, an acryl group, a methacryl group, an allyl group, or a styryl group is preferable.

That is, in the present invention, the crosslinking agent is preferably a compound having a group having an ethylenically unsaturated bond.

From the viewpoint of developability and heat resistance, the crosslinking agent preferably includes at least one type of di- or higher functional crosslinking agent containing two or more polymerizable groups, and more preferably include at least one type of tri- or higher functional crosslinking group. Among these, for the reason of being capable of further improving developability and heat resistance, a di- or higher functional crosslinking agent having two or more groups having an ethylenically unsaturated bond is particularly preferable.

In addition, the photosensitive resin composition of the present invention may contain a compound having an epoxy group as a polymerizable group, and for the reason of being capable of further improving developability and heat resistance, the content of the compound having an epoxy group in 100 parts by mass of the crosslinking agent is preferably 10% by mass or less, preferably 5% by mass or less, and particularly preferably, the compound is substantially not contained. Substantially not containing, for example, means that the content of the compound having an epoxy group is preferably 1% by mass or less, more preferably 0.5% by mass or less, particularly preferably 0.1% by mass or less, and the compound is particularly preferably not contained.

Specific examples of the crosslinking agent include a radically polymerizable compound (B1) and an ionically polymerizable compound (B2).

<<Radically Polymerizable Compound (B1)>>

Examples of the radically polymerizable compound (B1) include a (meth)acrylamide compound (B11) having 3 to 35 carbon atoms, a (meth)acrylate compound (B12) having 4 to 35 carbon atoms, an aromatic vinyl compound (B13) having 6 to 35 carbon atoms, a vinyl ether compound (B14) having 3 to 20 carbon atoms, and other radically polymerizable compounds (B15). The radically polymerizable compound (B1) may be used alone or in combination of two or more types thereof. In addition, as necessary, a polymerization inhibitor such as hydroquinone and methyl ether hydroquinone may be used in combination.

Examples of the (meth)acrylate compound (B12) having 4 to 35 carbon atoms include the following di- to hexafunctional (meth)acrylates. Hereinafter, EO represents ethylene oxide, and PO represents propylene oxide.

Examples of the difunctional (meth)acrylate include 1,4-butane di(meth)acrylate, 1,6-hexane diacrylate, polypropylene diacrylate, 1,6-hexanediol di(meth)acrylate, 1,10-decanediol di(meth)acrylate, neopentyl diacrylate, neopentyl glycol di(meth)acrylate, 2,4-dimethyl-1,5-pentanediol di(meth)acrylate, butylethylpropanediol (meth)acrylate, ethoxylated cyclohexanemethanol di(meth)acrylate, polyethylene glycol di(meth)acrylate, oligoethylene glycol di(meth)acrylate, ethylene glycol di(meth)acrylate, 2-ethyl-2-butyl-butanediol di(meth)acrylate, hydroxypivalic acid neopentyl glycol di(meth)acrylate, EO-modified bisphenol A di(meth)acrylate, bisphenol F polyethoxy di(meth)acrylate, polypropylene glycol di(meth)acrylate, oligopropylene glycol di(meth)acrylate, 1,4-butanediol di(meth)acrylate, 2-ethyl-2-butyl-propanediol di(meth)acrylate, 1,9-nonane di(meth)acrylate, propoxylated ethoxylated bisphenol A di(meth)acrylate, and tricyclodecane di(meth)acrylate.

Examples of the trifunctional (meth)acrylate include trimethylolpropane tri(meth)acrylate, trimethylolethane tri(meth)acrylate, alkylene oxide-modified tri(meth)acrylate of trimethylolpropane, pentaerythritol tri(meth)acrylate, dipentaerythritol tri(meth)acrylate, trimethylolpropane tri((meth)acryloyloxypropyl)ether, isocyanuric acid alkylene oxide-modified tri(meth)acrylate, propionic acid dipentaerythritol tri(meth)acrylate, tri((meth)acryloyloxyethyl) isocyanurate, hydroxypivalaldehyde-modified dimethylol propane tri(meth)acrylate, sorbitol tri(meth)acrylate, propoxylated trimethylolpropane tri(meth)acrylate, and ethoxylated glycerol triacrylate.

Examples of the tetrafunctional (meth)acrylate include pentaerythritol tetra(meth)acrylate, sorbitol tetra(meth)acrylate, ditrimethylolpropane tetra(meth)acrylate, propionic acid dipentaerythritol tetra(meth)acrylate, and ethoxylated pentaerythritol tetra(meth)acrylate.

Examples of the pentafunctional (meth)acrylate include sorbitol penta(meth)acrylate and dipentaerythritol penta(meth)acrylate.

Examples of the hexafunctional (meth)acrylate include dipentaerythritol hexa(meth)acrylate, sorbitol hexa(meth)acrylate, alkylene oxide-modified hexa(meth)acrylate of phosphazene, and caprolactone-modified dipentaerythritol hexa(meth)acrylate.

Examples of the vinyl ether compound (B14) having 3 to 35 carbon atoms include the following polyfunctional vinyl ethers.

Examples of the polyfunctional vinyl ether include divinyl ethers such as ethylene glycol divinyl ether, diethylene glycol divinyl ether, polyethylene glycol divinyl ether, propylene glycol divinyl ether, butylene glycol divinyl ether, hexanediol divinyl ether, bisphenol A alkylene oxide divinyl ether, and bisphenol F alkylene oxide divinyl ether, trimethylolethane trivinyl ether, trimethylolpropane trivinyl ether, ditrimethylolpropane tetravinyl ether, glycerin trivinyl ether, pentaerythritol tetravinyl ether, dipentaerythritol pentavinyl ether, dipentaerythritol hexavinyl ether, ethylene oxide-added trimethylolpropane trivinyl ether, propylene oxide-added trimethylolpropane trivinyl ether, ethylene oxide-added ditrimethylolpropane tetravinyl ether, propylene oxide-added ditrimethylolpropane tetravinyl ether, ethylene oxide-added pentaerythritol tetravinyl ether, propylene oxide-added pentaerythritol tetravinyl ether, ethylene oxide-added dipentaerythritol hexavinyl ether, and propylene oxide-added dipentacrythritol hexavinyl ether.

Examples of other radically polymerizable compounds (B15) include vinyl ester compounds (vinyl acetate, vinyl propionate, vinyl versatate, and the like), an allyl ester compound (allyl acetate and the like), a halogen-containing monomer (vinylidene chloride, vinyl chloride, and the like), and olefin compounds (ethylene, propylene, and the like).

Among these, from the viewpoint of a polymerization rate, the (meth)acrylamide compound (B11) or the (meth)acrylate compound (B12) is preferable, and the (meth)acrylate compound (B12) is particularly preferable.

<Ionically Polymerizable Compound (B2)>

Examples of the ionically polymerizable compound (B2) include an epoxy compound (B21) having 3 to 20 carbon atoms and an oxetane compound (B22) having 4 to 20 carbon atoms.

Examples of the epoxy compound (B21) having 3 to 20 carbon atoms include the following polyfunctional epoxy compounds.

Examples of the polyfunctional epoxy compound include bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, an epoxy novolac resin, hydrogenated bisphenol A diglycidyl ether, hydrogenated bisphenol F diglycidyl ether, hydrogenated bisphenol S diglycidyl ether, 3,4-epoxycyclohexylmethyl-3′,4′-epoxycyclohexane carboxylate, 2-(3,4-epoxycyclohexyl-5,5-spiro-3,4-epoxy)cyclohexane-meta-dioxane, bis(3,4-epoxycyclohexylmethyl)adipate, vinyl cyclohexene oxide, 4-vinyl epoxycyclohexane, bis(3,4-epoxy-6-methylcyclohexylmethyl)adipate, 3,4-epoxy-6-methylcyclohexyl-3′,4′-epoxy-6′-methylcyclohexane carboxylate, methylene bis(3,4-epoxycyclohexane), dicyclopentadiene diepoxide, ethylene glycol di(3,4-epoxycyclohexylmethyl)ether, ethylene bis(3,4-epoxycyclohexanecarboxylate), dioctyl epoxyhexahydrophthalate, di-2-ethylhexyl epoxyhexahydrophthalate, 1,4-butanediol diglycidyl ether, 1,6-hexanediol diglycidyl ether, glycerin triglycidyl ether, trimethylolpropane triglycidyl ether, polyethylene glycol diglycidyl ether, polypropylene glycol diglycidyl ethers, 1,1,3-tetradecadiene dioxide, limonene dioxide, 1,2,7,8-diepoxyoctane, and 1,2,5,6-diepoxycyclooctane.

Among these epoxy compounds, from the viewpoint of an excellent polymerization rate, an aromatic epoxide or an alicyclic epoxide is preferable, and an alicyclic epoxide is particularly preferable.

Examples of the oxetane compound (B22) having 4 to 20 carbon atoms include a compounds having 2 to 6 oxetane rings.

Examples of the compound having 2 to 6 oxetane rings include 3,7-bis(3-oxetanyl)-5-oxa-nonane, 3,3′-(1,3-(2-methylenyl)propanediyl bis(oxymethylene))bis-(3-ethyloxetane), 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)methyl]propane, ethylene glycol bis(3-ethyl-3-oxetanylmethyl)ether, dicyclopentenyl bis(3-ethyl-3-oxetanylmethyl)ether, triethylene glycol bis(3-ethyl-3-oxetanylmethyl)ether, tetraethylene glycol bis(3-ethyl-3-oxetanylmethyl)ether, tricyclodecanediyl dimethylene(3-ethyl-3-oxetanylmethyl)ether, trimethylolpropane tris(3-ethyl-3-oxetanylmethyl)ether, 1,4-bis(3-ethyl-3-oxetanylmethoxy)butane, 1,6-bis(3-ethyl-3-oxetanylmethoxy)hexane, pentaerythritol tris(3-ethyl-3-oxetanylmethyl)ether, pentaerythritol tetrakis(3-ethyl-3-oxetanylmethyl)ether, polyethylene glycol bis(3-ethyl-3-oxetanylmethyl)ether, dipentaerythritol hexakis(3-ethyl-3-oxetanylmethyl)ether, dipentaerythritol pentakis(3-ethyl-3-oxetanylmethyl)ether, dipentaerythritol tetrakis(3-ethyl-3-oxetanylmethyl)ether, caprolactone-modified dipentaerythritol hexakis(3-ethyl-3-oxetanylmethyl)ether, caprolactone-modified dipentaerythritol pentakis(3-ethyl-3-oxetanylmethyl)ether, ditrimethylolpropane tetrakis(3-ethyl-3-oxetanylmethyl)ether, EO-modified bisphenol A bis(3-ethyl-3-oxetanylmethyl)ether, PO-modified bisphenol A bis(3-ethyl-3-oxetanylmethyl)ether, EO-modified hydrogenated bisphenol A bis(3-ethyl-3-oxetanylmethyl)ether, PO-modified hydrogenated bisphenol A bis(3-ethyl-3-oxetanylmethyl)ether, and EO-modified bisphenol F (3-ethyl-3-oxetanylmethyl)ether.

As the crosslinking agent, a compound having two or more of one or more types of polymerizable groups selected from an epoxy group, an acryl group, a methacryl group, an allyl group, and a styryl group is preferable, a compound having two or more of one or more types of polymerizable groups selected from an acryl group, a methacryl group, an allyl group, and a styryl group is more preferable, and a compound having two or more of one or more types of polymerizable groups selected from an acryl group, a methacryl group, an allyl group, and a styryl group and having the following partial structure is still more preferable. If the crosslinking agent has the following partial structure, the heat resistance can be further improved.

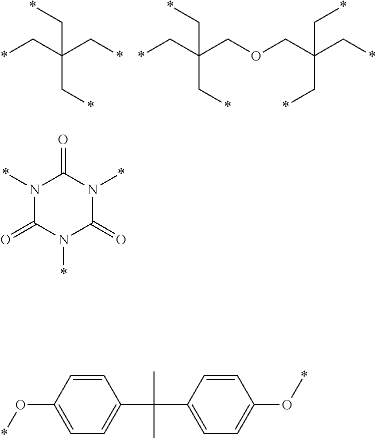

* in the formula is a linking arm.

Examples of commercially available crosslinking agents include A-9300, A-TMPT, A-TMMT, AD-TMP, A-DPH, A-BPE-4, and 4G (manufactured by Shin-Nakamura Chemical Co., Ltd., (meth)acrylate compound).

The content of the crosslinking agent in the photosensitive resin composition of the present invention is preferably 5% to 75% by mass, more preferably 10% to 70% by mass, and still more preferably 10% to 60% by mass, with respect to the total solid content in the photosensitive resin composition, from the viewpoint of good developability, adhesive strength, and heat resistance.

In addition, the ratio (molar ratio) of the crosslinking agent to the maleimide-based polymer described above (crosslinking agent/maleimide-based polymer) is preferably 90/10 to 10/90, and more preferably 20/80 to 80/20.

The crosslinking agent may be used alone or in combination of two or more types thereof. In the case of using two or more types thereof in combination, the total is preferably the above content.

<Monofunctional Polymerizable Compound>

The photosensitive resin composition of the present invention may contain a monofunctional polymerizable compound having a polymerizable group. The polymerizable group has the same range as that described for the crosslinking agent described above, and the preferable range thereof is also the same.

Examples of the monofunctional polymerizable compound include monofunctional (meth)acrylate, monofunctional (meth)acrylamide, an aromatic vinyl compound, a monofunctional vinyl ether, a compounds having one oxetane ring.

Examples of the monofunctional (meth)acrylate include ethyl (meth)acrylate, hexyl (meth)acrylate, 2-ethylhexyl (meth)acrylate, tert-octyl (meth)acrylate, isoamyl (meth)acrylate, decyl (meth)acrylate, isodecyl (meth)acrylate, stearyl (meth)acrylate, isostearyl (meth)acrylate, cyclohexyl (meth)acrylate, 4-n-butylcyclohexyl (meth)acrylate, bornyl (meth)acrylate, isobornyl (meth)acrylate, benzyl (meth)acrylate, 2-ethylhexyl diglycol (meth)acrylate, butoxyethyl (meth)acrylate, 2-chloroethyl (meth)acrylate, 4-bromobutyl (meth)acrylate, cyanoethyl (meth)acrylate, benzyl (meth)acrylate, butoxymethyl (meth)acrylate, methoxypropylene monoacrylate, 3-methoxybutyl (meth)acrylate, alkoxymethyl (meth)acrylate, 2-ethylhexyl carbitol (meth)acrylate, alkoxyethyl (meth)acrylate, 2-(2-methoxyethoxy)ethyl (meth)acrylate, 2-(2-butoxyethoxy)ethyl (meth)acrylate, 2,2,2-tetrafluoroethyl (meth)acrylate, 1H,1H,2H,2H-perfluorodecyl (meth)acrylate, 4-butylphenyl (meth)acrylate, phenyl (meth)acrylate, 2,4,5-tetramethylphenyl (meth)acrylate, 4-chlorophenyl (meth)acrylate, phenoxymethyl (meth)acrylate, phenoxyethyl (meth)acrylate, glycidyl (meth)acrylate, glycidyloxybutyl (meth)acrylate, glycidyloxyethyl (meth)acrylate, glycidyloxypropyl (meth)acrylate, diethylene glycol monovinyl ether monoacrylate, tetrahydrofurfuryl (meth)acrylate, hydroxyalkyl (meth)acrylate, 2-hydroxyethyl (meth)acrylate, 3-hydroxypropyl (meth)acrylate, 2-hydroxypropyl (meth)acrylate, 2-hydroxybutyl (meth)acrylate, 4-hydroxybutyl (meth)acrylate, dimethylaminoethyl (meth)acrylate, diethylaminoethyl (meth)acrylate, dimethylaminopropyl (meth)acrylate, diethylaminopropyl (meth)acrylate, trimethoxysilylpropyl (meth)acrylate, trimethoxysilylpropyl (meth)acrylate, trimethylsilylpropyl (meth)acrylate, polyethylene oxide monomethyl ether (meth)acrylate, oligoethylene oxide monomethyl ether (meth)acrylate, polyethylene oxide (meth)acrylate, oligoethylene oxide (meth)acrylate, oligoethylene oxide monoalkyl ether (meth)acrylate, polyethylene oxide monoalkyl ether (meth)acrylate, dipropylene glycol (meth)acrylate, polypropylene oxide monoalkyl ether (meth)acrylate, oligopropylene oxide monoalkyl ether (meth)acrylate, 2-methacryloyloxyethyl succinate, 2-methacryloyloxyhexahydrophthalate, 2-methacryloyloxyethyl-2-hydroxypropyl phthalate, butoxy diethylene glycol (meth)acrylate, trifluoroethyl (meth)acrylate, perfluorooctylethyl (meth)acrylate, 2-hydroxy-3-phenoxypropyl (meth)acrylate, EO-modified phenol (meth)acrylate, EO-modified cresol (meth)acrylate, EO-modified nonylphenol (meth)acrylate, PO-modified nonylphenol (meth)acrylate, and EO-modified 2-ethylhexyl (meth)acrylate.

Examples of the monofunctional (meth)acrylamide compound include (meth)acrylamide, N-methyl (meth)acrylamide, N-ethyl (meth)acrylamide, N-propyl (meth)acrylamide, N-n-butyl (meth)acrylamide, N-t-butyl (meth)acrylamide, N-butoxymethyl (meth)acrylamide, N-isopropyl (meth)acrylamide, N-methylol (meth)acrylamide, N,N-dimethyl (meth)acrylamide, N,N-diethyl (meth)acrylamide, and (meth)acryloylmorpholine.

Examples of the monofunctional aromatic vinyl compound (B13) include vinyl thiophene, vinyl furan, vinyl pyridine, styrene, methyl styrene, trimethyl styrene, ethyl styrene, isopropyl styrene, chloromethyl styrene, methoxystyrene, acetoxystyrene, chlorostyrene, dichlorostyrene, bromostyrene, vinyl benzoic acid methyl ester, 3-methyl styrene, 4-methyl styrene, 3-ethyl styrene, 4-ethyl styrene, 3-propyl styrene, 4-propyl styrene, 3-butyl styrene, 4-butyl styrene, 3-hexyl styrene, 4-hexyl styrene, 3-octyl styrene, 4-octyl styrene, 3-(2-ethylhexyl)styrene, 4-(2-ethylhexyl)styrene, allyl styrene, isopropenyl styrene, butenyl styrene, octenyl styrene, 4-t-butoxycarbonyl styrene, 4-methoxystyrene, and 4-t-butoxystyrene.

Examples of the monofunctional vinyl ether include methyl vinyl ether, ethyl vinyl ether, propyl vinyl ether, n-butyl vinyl ether, t-butyl vinyl ether, 2-ethylhexyl vinyl ether, n-nonyl vinyl ether, lauryl vinyl ether, cyclohexyl vinyl ether, cyclohexylmethyl vinyl ether, 4-methylcyclohexylmethyl vinyl ether, benzyl vinyl ether, dicyclopentenyl vinyl ether, 2-dicyclopentenoxyethyl vinyl ether, methoxyethyl vinyl ether, ethoxyethyl vinyl ether, butoxyethyl vinyl ether, methoxyethoxyethyl vinyl ether, ethoxyethoxyethyl vinyl ether, methoxypolyethylene glycol vinyl ether, tetrahydrofurfuryl vinyl ether, 2-hydroxyethyl vinyl ether, 2-hydroxypropyl vinyl ether, 4-hydroxybutyl vinyl ether, 4-hydroxymethylcyclohexylmethyl vinyl ether, diethylene glycol monovinyl ether, polyethylene glycol vinyl ether, chloroethyl vinyl ether, chlorobutyl vinyl ether, chloroethoxyethyl vinyl ether, phenylethyl vinyl ether, and phenoxypolyethylene glycol vinyl ether.

Examples of the monofunctional epoxy compound include phenyl glycidyl ether, p-tert-butylphenyl glycidyl ether, butyl glycidyl ether, 2-ethylhexyl glycidyl ether, allyl glycidyl ether, 1,2-butylene oxide, 1,3-butadiene monoxide, 1,2-epoxydodecane, epichlorohydrin, 1,2-epoxydecane, styrene oxide, cyclohexene oxide, 3-methacryloyloxymethyl cyclohexene oxide, 3-acryloyloxymethyl cyclohexene oxide, and 3-vinyl cyclohexene oxide.

Examples of the compound having one oxetane ring include 3-ethyl-3-hydroxymethyl oxetane, 3-(meth)allyloxymethyl-3-ethyloxetane, (3-ethyl-3-oxetanylmethoxy)methyl benzene, 4-fluoro-[1-(3-ethyl-3-oxetanylmethoxy)methyl]benzene, 4-methoxy-[1-(3-ethyl-3-oxetanylmethoxy)methyl]benzene, [1-(3-ethyl-3-oxetanylmethoxy)ethyl]phenyl ether, isobutoxymethyl (3-ethyl-3-oxetanylmethyl)ether, isobornyloxyethyl (3-ethyl-3-oxetanylmethyl)ether, isobornyl (3-ethyl-3-oxetanylmethyl)ether, 2-ethylhexyl (3-ethyl-3-oxetanylmethyl)ether, ethyl diethylene glycol (3-ethyl-3-oxetanylmethyl)ether, dicyclopentadiene (3-ethyl-3-oxetanylmethyl)ether, dicyclopentenyloxyethyl (3-ethyl-3-oxetanylmethyl)ether, dicyclopentenyl (3-ethyl-3-oxetanylmethyl)ether, tetrahydrofurfuryl (3-ethyl-3-oxetanylmethyl)ether, tetrabromophenyl (3-ethyl-3-oxetanylmethyl)ether, 2-tetrabromophenoxyethyl (3-ethyl-3-oxetanylmethyl)ether, tribromophenyl (3-ethyl-3-oxetanylmethyl)ether, 2-tribromophenoxyethyl (3-ethyl-3-oxetanylmethyl)ether, 2-hydroxyethyl (3-ethyl-3-oxetanylmethyl)ether, 2-hydroxypropyl (3-ethyl-3-oxetanylmethyl)ether, butoxyethyl (3-ethyl-3-oxetanylmethyl)ether, pentachlorophenyl (3-ethyl-3-oxetanylmethyl)ether, pentabromophenyl (3-ethyl-3-oxetanylmethyl)ether, and bornyl (3-ethyl-3-oxetanylmethyl)ether.

In a case where the photosensitive resin composition of the present invention contains a monofunctional polymerizable compound, the content of the monofunctional polymerizable compound is preferably 0.1 to 200 parts by mass, and more preferably 1 to 100 parts by mass, with respect to 100 parts by mass of the crosslinking agent.

The monofunctional polymerizable compound may be used alone or in combination of two or more types thereof. In the case of using two or more types thereof in combination, the total is preferably the above content.

<Photopolymerization Initiator>

The photosensitive resin composition of the present invention contains a photopolymerization initiator.

By containing a photopolymerization initiator in the photosensitive resin composition of the present invention, curing by radicals or an acid occurs by forming a layered photosensitive resin composition layer by applying the photosensitive resin composition to a semiconductor wafer and irradiating with light, and thus, the adhesiveness in the portion irradiated with light can be reduced. If light irradiation is performed, for example, through a photomask, there is an advantage in that regions having different adhesive forces can be simply formed depending on the pattern of the photomask.

The photopolymerization initiator is not particularly limited as long as it has an ability to initiate a polymerization reaction (crosslinking reaction) of a crosslinking agent, and can be appropriately selected from known photopolymerization initiators. For example, the photopolymerization initiator preferably has photosensitivity with respect to from the ultraviolet region to the visible light. In addition, the photopolymerization initiator may be an activator generating active radicals by a certain action with a photoexcited sensitizer. A compound generating radicals or an acid by light irradiation is preferable.

In addition, the photopolymerization initiator preferably contains at least one type of compound having a molar light absorption coefficient of at least about 50 within a range of about 300 nm to 800 nm (preferably 330 nm to 500 nm).

As the photopolymerization initiator, known compounds can be used without limitation. Examples thereof include halogenated hydrocarbon derivatives (for example, halogenated hydrocarbon derivatives having a triazine skeleton, halogenated hydrocarbon derivatives having an oxadiazole skeleton, and halogenated hydrocarbon derivatives having a trihalomethyl group), acylphosphine compounds such as acylphosphine oxide, hexaarylbiimidazole, oxime compounds such as oxime derivatives, organic peroxides, thio compounds, ketone compounds, aromatic onium salts, keto oxime ethers, aminoacetophenone compounds, hydroxyacetophenones, azo compounds, azide compounds, metallocene compounds, organic boron compounds, and iron arene complexes.

Examples of the halogenated hydrocarbon compound having a triazine skeleton include the compounds described in Bull. Chem. Soc. Japan, 42, 2924 (1969) written by Wakabayashi et al., the compounds described in GB1388492B, the compounds described in JP1978-133428A (JP-S53-133428A), the compounds described in DE3337024B, the compounds described in J. Org. Chem.; 29, 1527 (1964) by F. C. Schaefer et al., the compounds described in JP1987-58241A (JP-S62-58241A), the compounds described in JP1993-281728A (JP-H05-281728A), the compounds described in JP1993-34920A (JP-H05-34920A), and the compounds described in U.S. Pat. No. 4,212,976A.

Examples of the compounds described in U.S. Pat. No. 4,212,976A include compounds having an oxadiazole skeleton (for example, 2-trichloromethyl-5-phenyl-1,3,4-oxadiazole, 2-trichloromethyl-5-(4-chlorophenyl)-1,3,4-oxadiazole, 2-trichloromethyl-5-(1-naphthyl)-1,3,4-oxadiazole, 2-trichloromethyl-5-(2-naphthyl)-1,3,4-oxadiazole, 2-tribromomethyl-5-phenyl-1,3,4-oxadiazole, 2-tribromomethyl-5-(2-naphthyl)-1,3,4-oxadiazole; 2-trichloromethyl-5-styryl-1,3,4-oxadiazole, 2-trichloromethyl-5-(4-chlorostyryl)-1,3,4-oxadiazole, 2-trichloromethyl-5-(4-methoxystyryl)-1,3,4-oxadiazole, 2-trichloromethyl-5-(1-naphthyl)-1,3,4-oxadiazole, 2-trichloromethyl-5-(4-n-butoxystyryl)-1,3,4-oxadiazole, and 2-tribromomethyl-5-styryl-1,3,4-oxadiazole).

In addition, examples of photopolymerization initiators other than the photopolymerization initiators described above include acridine derivatives (for example, 9-phenylacridine and 1,7-bis(9,9′-acridinyl)heptane), N-phenylglycine, polyhalogen compounds (for example, carbon tetrabromide, phenyltribromomethyl sulfone and phenyltrichloromethyl ketone), coumarins (for example, 3-(2-benzofuranoyl)-7-diethylamino coumarin, 3-(2-benzofuroyl)-7-(l-pyrrolidinyl) coumarin, 3-benzoyl-7-diethylamino coumarin, 3-(2-methoxybenzoyl)-7-diethylamino coumarin, 3-(4-dimethylaminobenzoyl)-7-diethylamino coumarin, 3,3′-carbonylbis(5,7-di-n-propoxycoumarin), 3,3′-carbonylbis(7-diethylaminocoumarin), 3-benzoyl-7-methoxy coumarin, 3-(2-furoyl)-7-diethylamino coumarin, 3-(4-diethylaminocinnamoyl)-7-diethylamino coumarin, 7-methoxy-3-(3-pyridylcarbonyl) coumarin, 3-benzoyl-5,7-dipropoxy coumarin, 7-benzotriazole-2-yl coumarin, and the coumarin compounds described in JP1993-19475A (JP-H5-19475A), JP1995-271028A (JP-H7-271028A), JP2002-363206A, JP2002-363207A, JP2002-363208A, or JP2002-363209A), acyl phosphine oxides (for example, bis(2,4,6-trimethylbenzoyl)-phenylphosphine oxide, bis(2,6-dimethoxybenzoyl)-2,4,4-trimethyl-pentylphenylphosphine oxide, and LucirinTPO), metallocenes (for example, bis(η5-2,4-cyclopentadien-1-yl)-bis(2,6-difluoro-3-(1H-pyrrol-1-yl)-phenyl)titanium, and η5-cyclopentadienyl-η6-cumenyl-iron(1+)-hexafluorophosphate(1−)), and the compounds described in JP1978-133428A (JP-S53-133428A), JP1978-1819B (JP-S57-1819B), JP1978-6096B (JP-S57-6096B), or U.S. Pat. No. 3,615,455A.

Examples of the ketone compound include benzophenone, 2-methylbenzophenone, 3-methylbenzophenone, 4-methylbenzophenone, 4-methoxybenzophenone, 2-chlorobenzophenone, 4-chlorobenzophenone, 4-bromobenzophenone, 2-carboxybenzophenone, 2-ethoxycarbonylbenzophenone, benzophenone tetracarboxylic acid or tetramethyl ester thereof, 4,4′-bis(dialkylamino)benzophenones (for example, 4,4′-bis(dimethylamino)benzophenone, 4,4′-bis(dicyclohexylamino)benzophenone, 4,4′-bis(diethylamino)benzophenone, 4,4′-bis(dihydroxyethylamino)benzophenone), 4-methoxy-4′-dimethylaminobenzophenone, 4,4′-dimethoxybenzophenone, 4-dimethylaminobenzophenone, 4-dimethylaminoacetophenone, benzyl, anthraquinone, 2-t-butylanthraquinone, 2-methylanthraquinone, phenanthraquinone, xanthone, thioxanthone, 2-chloro-thioxanthone, 2,4-diethylthioxanthone, fluorenone, 2-benzyl-dimethylamino-1-(4-morpholinophenyl)-1-butanone, 2-methyl-1-[4-(methylthio)phenyl]-2-morpholino-1-propanone, and a 2-hydroxy-2-methyl-[4-(1-methylvinyl)phenyl]propanol oligomer, benzoin, benzoin ethers (for example, benzoin methyl ether, benzoin ethyl ether, benzoin propyl ether, benzoin isopropyl ether, benzoin phenyl ether, and benzyl dimethyl ketal), acridone, chloroacridone, N-methylacridone, N-butylacridone, and N-butyl-chloroacridone.

As the photopolymerization initiator, a hydroxyacetophenone compound, an aminoacetophenone compound, or an acyl phosphine compound can also be suitably used. More specifically, for example, the aminoacetophenone-based initiators described in JP1998-291969A (JP-H10-291969A) and the acylphosphine oxide-based initiators described in JP4225898B can also be used.

As the hydroxyacetophenone-based initiator, IRGACURE-184, DAROCUR-1173, IRGACURE-500, IRGACURE-2959, or IRGACURE-127 (trade name: manufactured by BASF SE) can be used. As the aminoacetophenone-based initiator, a commercially available product IRGACURE-907, IRGACURE-369, or IRGACURE-379 (trade name: manufactured by BASF SE) can be used. As the aminoacetophenone-based initiator, the compounds described in JP2009-191179A of which the absorption wavelength is matched to a light source of a long wavelength such as 365 nm or 405 nm can also be used. In addition, as the acyl phosphine-based initiator, a commercially available product IRGACURE-819 or DAROCUR-TPO (trade name: manufactured by BASF SE) can be used.

As the photopolymerization initiator, more preferably, an oxime-based compound is exemplified. As the oxime-based initiator, specifically, the compounds described in JP2001-233842A, JP2000-80068A, or JP2006-342166A can be used.

Examples of the oxime compound suitably used as the photopolymerization initiator in the present invention include 3-benzoyloxyiminobutan-2-one, 3-acetoxyiminobutan-2-one, 3-propionyloxyiminobutan-2-one, 2-acetoxyimonopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Examples of the oxime ester compound include the compounds described in J.C.S. Perkin II (1979) pp. 1653-1660), J.C.S. Perkin II (1979) pp. 156-162, or Journal of Photopolymer Science and Technology (1995) pp. 202-232, and the compounds described in JP2000-66385A, JP2000-80068A, JP2004-534797A, or JP2006-342166A.

As the commercially available product, IRGACURE-OXE01 (manufactured by BASF SE), IRGACURE-OXE02 (manufactured by BASF SE), or N-1919 (manufactured by ADEKA CORPORATION) is also suitably used.

In addition, as oxime ester compounds other than the oxime ester compounds described above, the compounds in which oxime has been linked to the carbazole N-position described in JP2009-519904A, the compounds in which a hetero substituent has been introduced into the benzophenone position described in U.S. Pat. No. 7,626,957B, the compounds in which a nitro group has been introduced into the coloring agent portion described in JP2010-15025A or US2009/292039A, the ketoxime-based compounds described in WO2009/131189A, the compounds containing a triazine skeleton and an oxime skeleton in the same molecule described in U.S. Pat. No. 7,556,910B, or the compounds having an absorption maximum at 405 nm and having good sensitivity to a g-line light source described in JP2009-221114A may be used.

More preferably, the cyclic oxime compounds described in JP2007-231000A or JP2007-322744A can be suitably used. Among the cyclic oxime compounds, in particular, the cyclic oxime compounds condensed with a carbazole coloring agent described in JP2010-32985A or JP2010-185072A are preferable from the viewpoint of having a high light absorption and improving sensitivity.

In addition, the compounds having an unsaturated bond at a specific portion of the oxime compound described in JP2009-242469A can be suitably used since high sensitivity can be achieved by regenerating active radicals from the polymerization inert radicals.

Most preferably, the oxime compounds having a specific substituent shown in JP2007-269779A or the oxime compounds having a thioaryl group shown in JP2009-191061A are exemplified.

From the viewpoint of exposure sensitivity, the photopolymerization initiator is preferably a compound selected from the group consisting of a trihalomethyltriazine compound, a benzyl dimethyl ketal compound, an a-hydroxyketone compound, an α-aminoketone compound, an acylphosphine compound, a phosphine oxide compound, a metallocene compound, an oxime compound, a triallylimidazole dimer, an onium compound, a benzothiazole compound, a benzophenone compound, an acetophenone compound and derivatives thereof, a cyclopentadiene-benzene-iron complex and salts thereof, a halomethyloxadiazole compound, and a 3-aryl substituted coumarin compound. The photopolymerization initiator is more preferably a trihalomethyltriazine compound, an α-aminoketone compound, an acylphosphine compound, a phosphine oxide compound, an oxime compound, a triallylimidazole dimer, an onium compound, a benzophenone compound, or an acetophenone compound. The photopolymerization initiator is particularly preferably at least one compound selected from the group consisting of a trihalomethyltriazine compound, an α-aminoketone compound, an oxime compound, a triallylimidazole dimer, and a benzophenone compound. An oxime compound is particularly preferable.

In addition, as the photopolymerization initiator, a compound generating an acid having a pKa of 4 or less can also be preferably used, and a compound generating an acid having a pKa of 3 or less is more preferable.

Examples of the compound generating an acid include trichloromethyl-s-triazines, a sulfonium salt or an iodonium salt, quaternary ammonium salts, a diazomethane compound, an imide sulfonate compound, and an oxime sulfonate compound. Among these, from the viewpoint of high-sensitivity, an oxime sulfonate compound is preferably used. These acid generators can be used alone or in combination of two or more types thereof.

Specific examples thereof include the acid generators described in paragraphs [0073] to [0095] of JP2012-8223A.

The molar light absorption coefficient of the photopolymerization initiator can be obtained by a known method. Specifically, for example, the molar light absorption coefficient is preferably measured at a concentration of 0.01 g/L using an ethyl acetate solvent, using a UV-visible spectrophotometer (Carry-5 spctrophotometer manufactured by VARIAN Inc.).

The content of the photopolymerization initiator in the photosensitive resin composition of the present invention is preferably 0.1% to 50% by mass, more preferably 0.1% to 30% by mass, and particularly preferably 0.1% to 20% by mass, with respect to the total solid content in the photosensitive resin composition.

In addition, the content of the photopolymerization initiator in the photosensitive resin composition of the present invention is preferably 0.1 to 30 parts by mass, more preferably 0.2 to 20 parts by mass, and still more preferably 1 to 20 parts by mass, with respect to 100 parts by mass of the crosslinking agent.

The photopolymerization initiator may be used alone or in combination of two or more types thereof. In the case of using two or more types thereof in combination, the total is preferably the above content.

<<Thermal Polymerization Initiator>>

The photosensitive resin composition of the present invention contains a thermal polymerization initiator.

By containing a thermal polymerization initiator in the photosensitive resin composition of the present invention, by forming a layered photosensitive resin composition by applying the photosensitive resin composition to a semiconductor wafer, binding the adherend, and heating, the photosensitive resin composition layer becomes more robust, and it is possible to suppress a cohesive failure of the photosensitive resin composition which is likely to occur at the time of performing a mechanical or chemical treatment of the adherend. That is, it is possible to improve the adhesiveness of the photosensitive resin composition layer. In addition, by using a photopolymerization initiator and a thermal polymerization initiator in combination, it is possible to improve the curability.

The 1-minute half-life period temperature of the thermal polymerization initiator is preferably 120° C. to 300° C., more preferably 150° C. to 250° C., still more preferably 150° C. to 230° C., and particularly preferably 170° C. to 200° C., from the viewpoint of the stability and the curability of the photosensitive resin composition. If the 1-minute half-life period temperature of the thermal polymerization initiator is the above lower limit value or greater, the coating film is not excessively cured when drying the coating film, and developability is good. If the 1-minute half-life period temperature of the thermal polymerization initiator is the above lower limit value or less, the curability is good.

The molecular weight of the thermal polymerization initiator is preferably 100 or greater, more preferably 150 or greater, still more preferably 200 or greater, and particularly preferably 250 or greater, from the viewpoint of volatility. The upper limit, for example, is preferably 1,000 or less, and more preferably 500 or less. If the molecular weight of the thermal polymerization initiator is the above lower limit value or greater, it is possible to effectively suppress volatilization of the thermal polymerization initiator when drying the coating film, and the curability is good.

As the thermal polymerization initiator, a compound generating radicals by heat (hereinafter, simply referred to as a thermal radical generator) or a compound generating an acid by heat (hereinafter, simply referred to as a thermal acid generator) can be used. In particular, a thermal radical generator is preferable. Since the thermal radical generator can promote the radical polymerization of an ethylenically unsaturated group, in the case of using a compound containing a group having an ethylenically unsaturated bond as a crosslinking agent, it is possible to effectively promote the polymerization reaction of the crosslinking agent, and it is possible to cure in a shorter period of time. Moreover, a reaction in which the polymerization reaction is initiated and promoted by a thermal acid generator is a ring-opening polymerization of epoxy. Since in the ring-opening polymerization of epoxy, the polymerization rate is slow compared to that in radical polymerization, the curability cannot be sufficiently promoted.

<<<Thermal Radical Generator>>>

As the thermal radical generator, known thermal radical generators can be used.

The thermal radical generator is a compound that generates radicals by heat energy, and initiates or promotes a polymerization reaction of a crosslinking agent.

Examples of the thermal radical generator include aromatic ketones, onium salt compounds, organic peroxides, thio compounds, hexaarylbiimidazole compounds, ketoxime ester compounds, borate compounds, azinium compounds, metallocene compounds, active ester compounds, compounds having a carbon-halogen bond, and azo-based compounds. Among these, organic peroxides or azo-based compounds are more preferable, and organic peroxides are particularly preferable.

Specific examples thereof include the compounds described in paragraphs [0074] to [0118] of JP2008-63554A.

In addition, examples of the commercially available products thereof include PERCUMYL D, PERCUMYL H, PERCUMYL ND, PERCUMYL P, PEROYL IB, PEROYL IP, PEROYL L, PEROYL NPP, PEROYL SA, PEROYL SBP, PEROYL TCP, PEROYL OPP, PEROYL 355, PERBUTYL D, PERBUTYL ND, PERBUTYL NHP, PERBUTYL PV, PERBUTYL P, PERBUTYL Z, PERBUTYL O, PERHEXYL ND, PERHEXYL O, PERHEXYL PV, PEROCTA ND, PEROCTA O, NYPER BMT, NYPER BW, NYPER PMB, PERHEXA HC, PERHEXA MC, PERHEXA TMH, PERHEXA V, PERHEXA 25B, PERHEXA 250, PERHEXYNE 25B, and PERMENTA H, manufactured by NOF CORPORATION.

<<<Thermal Acid Generator>>>

As the thermal acid generator, known thermal acid generators can be used.

The thermal acid generator, for example, is a compound generating sulfonic acid, carboxylic acid, or an acid having a low nucleophilicity such as disufonylimide, by heating. As the acid generated from the thermal acid generator, an acid having a pKa of 2 or less is preferable.

For example, a sulfonic acid, an alkylcarboxylic acid substituted with an electron withdrawing group, an aryl carboxylic acid, or disulfonylimide is preferable. Examples of the electron withdrawing group include a halogen atom such as a fluorine atom, a haloalkyl group such as a trifluoromethyl group, a nitro group, and a cyano group.

As the thermal acid generator, a sulfonic ester that does not substantially generate an acid by irradiation with active light or radiation and generates an acid by heat is preferably used. It can be determined that an acid is not substantially generated by irradiation with active light or radiation, by confirming no change in spectra by measurement of infrared absorption (IR) spectra before and after exposure of the compound and nuclear magnetic resonance (NMR) spectrum.

The molecular weight of sulfonic ester is preferably 230 to 1,000, and more preferably 230 to 800.

As the sulfonic ester, a commercially available product may be used or a sulfonic ester synthesized by a known method may be used. The sulfonic ester can be synthesized, for example, by reacting sulfonyl chloride or sulfonic acid anhydride with a corresponding polyhydric alcohol under basic conditions. As a commercially available product, cyclohexyl p-toluenesulfonate (manufactured by Tokyo Chemical Industry Co., Ltd.) is exemplified.

The content of the thermal polymerization initiator in the photosensitive resin composition of the present invention is preferably 0.01% to 50% by mass, more preferably 0.1% to 20% by mass, and particularly preferably 0.5% to 10% by mass, with respect to the total solid content in the photosensitive resin composition.

The content of the thermal polymerization initiator in the photosensitive resin composition of the present invention is preferably 1 to 500 parts by mass, and more preferably 10 to 200 parts by mass, with respect to 100 parts by mass of the photopolymerization initiator.

In addition, the content of the thermal polymerization initiator in the photosensitive resin composition of the present invention is preferably 0.1 to 30 parts by mass, more preferably 0.2 to 20 parts by mass, still more preferably 0.5 to 20 parts by mass, and particularly preferably 1 to 20 parts by mass, with respect to 100 parts by mass of the crosslinking agent.

The thermal polymerization initiator may be used alone or in combination of two or more types thereof. In the case of using two or more types thereof in combination, the total is preferably the above content.

The ratio of combination of the photopolymerization initiator and the thermal polymerization initiator is preferably 0.1 to 10:1, more preferably 0.2 to 5:1, and still more preferably 0.3 to 3:1 in a mass ratio.

<<Solvent>>

The photosensitive resin composition of the present invention can contain a solvent.

As the solvent, known solvents can be used without limitation. Examples of an organic solvent include esters, ethers, ketones, amides, alcohols, and hydrocarbons.

Examples of the esters include ethyl acetate, n-butyl acetate, isobutyl acetate, amyl formate, isoamyl acetate, isobutyl acetate, butyl propionate, isopropyl butyrate, ethyl butyrate, butyl butyrate, methyl lactate, ethyl lactate, oxyacetic acid alkyl esters (examples: methyl oxyacetate, ethyl oxyacetate, and butyl oxyacetate (for example, methyl methoxyacetate, ethyl methoxyacetate, butyl methoxyacetate, methyl ethoxyacetate, and ethyl ethoxyacetate)), 3-oxypropionic acid alkyl esters (examples: methyl 3-oxypropionate and ethyl 3-oxypropionate (for example, methyl 3-methoxypropionate, ethyl 3-methoxypropionate, methyl 3-ethoxypropionate, and ethyl 3-ethoxypropionate)), 2-oxypropionic acid alkyl esters (examples: methyl 2-oxypropionate, ethyl 2-oxypropionate, and propyl 2-oxypropionate (for example, methyl 2-methoxypropionate, ethyl 2-methoxypropionate, propyl 2-methoxypropionate, methyl 2-ethoxypropionate, and ethyl 2-ethoxypropionate)), methyl 2-oxy-2-methylpropionate and ethyl 2-oxy-2-methylpropionate (for example, methyl 2-methoxy-2-methylpropionate and ethyl 2-ethoxy-2-methylpropionate), methyl pyruvate, ethyl pyruvate, propyl pyruvate, methyl acetoacetate, ethyl acetoacetate, methyl 2-oxobutanoate, ethyl 2-oxobutanoate, 1-methoxy-2-propyl acetate, γ-butyrolactone, and δ-valerolactone.

Examples of the ethers include diethylene glycol dimethyl ether, tetrahydrofuran, ethylene glycol monomethyl ether, ethylene glycol monoethyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, and propylene glycol monopropyl ether acetate.

Examples of the ketones include methyl amyl ketone, methyl ethyl ketone, cyclopentanone, cyclohexanone, 2-heptanone, and 3-heptanone.

Examples of the amides include N,N-dimethylformamide, N,N-dimethylacetamide, and N-methyl-2-pyrrolidone.

Examples of the alcohols include methanol, ethanol, 1-propanol, 2-propanol, 1-butanol, 2-butanol, tert-butanol, 1-pentanol, and 1-methoxy-2-propanol.

Examples of the hydrocarbons include aromatic hydrocarbons and saturated aliphatic hydrocarbons.

As the aromatic hydrocarbons, toluene, xylene, anisole, or mesitylene is suitably exemplified.

Examples of the saturated aliphatic hydrocarbons include linear hydrocarbons such as hexane, heptane, octane, nonane, methyloctane, decane, undecane, dodecane, and tridecane, branched hydrocarbons having 3 to 15 carbon atoms, p-mentane, o-mentane, m-mentane, diphenyl mentane, 1,4-terpine, 1,8-terpine, bornane, norbornane, pinane, thujane, carane, and longifolene.

Examples of the hydrocarbons include a hydrocarbon in which a five-membered ring and a six-membered ring are combined with each other and a hydrocarbon in which two six-membered rings are combined with each other. Examples of the hydrocarbons in which a five-membered ring and a six-membered ring are combined with each other include indene, pentalene, indane, and tetrahydroindene, and examples of the hydrocarbon in which two six-membered rings are combined with each other include naphthalene, tetrahydronaphthalene (tetralin), and decahydronaphthalene (decalin).

Among these, as the solvent, l-methoxy-2-propyl acetate, γ-butyrolactone, δ-valerolactone, methyl amyl ketone, methyl ethyl ketone, cyclopentanone, or cyclohexanone can be preferably used.

From the viewpoint of improvement of the coating surface and the like, these solvents are preferably in a form where two or more types are mixed.

In a case where the photosensitive resin composition of the present invention has a solvent, the solvent is preferably used such that the concentration of solid contents of the photosensitive resin composition becomes 5% to 80% by mass.

The solvent may be only one type or two or more types. In a case where two or more types of solvents are present, the total is preferably within the above range.

<<Filler>>

The photosensitive resin composition of the present invention can contain a filler.

In the present invention, the filler is not particularly limited as long as it does not molecularly disperse in the film and it disperses in the solid state. As the filler which can be used in the present invention, an organic filler and an inorganic filler are exemplified.

As the organic filler, an organic crosslinked polymer (preferably PMMA crosslinked particles), low density polyethylene particles, high density polyethylene particles, polystyrene particles, various organic pigments, a micro balloon, a urea-formalin filler, polyester particles, a cellulose filler, and an organometal are exemplified.

As the organic pigments, known organic pigments are exemplified, and an indigo-based pigment, a quinacridone-based pigment, a dioxazine-based pigment, an isoindolinone-based pigment, a quinophthalone-based pigment, a dyed lake pigment, an Azine pigment, a nitroso pigment, a nitro pigment, a natural pigment, a fluorescent pigment, or carbon black can be used. In addition, the filler may contain an inorganic pigment.

Examples of the inorganic filler include alumina, titania, zirconia, kaolin, baked kaolin, talc, agalmatolite, diatomaceous earth, sodium carbonate, calcium carbonate, aluminum hydroxide, magnesium hydroxide, zinc oxide, lithopone, silicate mineral particles (preferably, amorphous silica, colloidal silica, baked gypsum, and silica), magnesium carbonate, titanium oxide, alumina, barium carbonate, barium sulfate, and mica.

The shape of the filler is not particularly limited, and a spherical shape, a layered shape, a fibrous shape, and a hollow balloon shape can be exemplified.

The average particle diameter (average primary particle diameter) of the filler is preferably 5 nm to 20 μm, more preferably from 10 nm to 10 μm, and particularly preferably 50 nm to 1 μm. If the average particle diameter is within the above range, the dispersion stability in the film is improved, and the surface shape or the pattern shape after exposure and development is excellent.

As the layered filler, an inorganic layered compound having a thin flat plate shape is preferably exemplified, and examples thereof include micas such as natural mica and synthetic mica represented by the following Formula (1), talc represented by 3MgO.4SiO.H₂O, taeniolite, montmorillonite, saponite, hectorite, and zirconium phosphate.

A(B,C)₂˜₅D₄O₁₀(OH,F,O)₂ (1)

In Formula (1), A represents any one of K, Na, and Ca, B and C each represent any one of Fe(II), Fe(III), Mn, Al, Mg, and V, and D represents Si or Al.

As the particle diameter of the layered filler, the average long diameter is preferably 0.3 to 20 μm, more preferably 0.5 to 10 μm, and particularly preferably 1 to 5 μm. In addition, the average thickness is preferably 0.1 m or less, more preferably 0.05 μm or less, and particularly preferably 0.01 μm or less.

For example, among the layered fillers, swelling synthetic mica is 1 to 50 nm in thickness and about 1 to 20 μm in surface size.

As the filler, commercially available products may be used. Examples of commercially available products thereof include R-972 (silica, manufactured by Nippon Aerosil Co., Ltd.) and AKP-50 (Alumina, manufactured by Sumitomo Chemical Co., Ltd.).

As the filler used in the present invention, alumina, silicate mineral particles, polystyrene particles, an organic crosslinked polymer, sodium carbonate, mica, or smectite is preferable, alumina, silicate mineral particles, an organic crosslinked polymer, or smectite is more preferable, and alumina or silicate mineral particles are still more preferable.

The photosensitive resin composition of the present invention may not contain a filler, but in the case of containing a filler, the photosensitive resin composition of the present invention is preferably 1% to 80% by mass, more preferably 1% to 75% by mass, and particularly preferably 1% to 70% by mass, with respect to the total solid content in the photosensitive resin composition.

The filler may be used alone or in combination of two or more types thereof. In the case of using two or more types thereof in combination, the total is preferably the above content.

<<Adhesiveness-Imparting Agent>>

In the photosensitive resin composition of the present invention, an adhesiveness-imparting agent can also be contained to improve the interfacial bond between different types of materials. Examples of the adhesiveness-imparting agent include a silane-based coupling agent, a titanium-based coupling agent, and an aluminum-based coupling agent, and among these, the silane-based coupling agent (silane coupling agent) is preferable from the viewpoint of high effects. The content of the adhesiveness-imparting agent is preferably 0.01% to 20% by mass and more preferably 0.1% to 15% by mass with respect to the total solid content in the photosensitive resin composition, from the viewpoint of the effects, heat resistance, and cost.

<<<Silane-Based Coupling Agent>>>

In the present invention, the silane coupling agent refers to a compound that has one or more functional groups (hereinafter, also referred to as a silane coupling group) in which at least one of an alkoxy group or a halogen group is directly bonded to a Si atom in the molecule. The silane coupling group is preferably a silane coupling group in which two or more of alkoxy groups or halogen atoms are directly bonded to a Si atom, and particularly preferably a silane coupling group in which three or more of alkoxy groups or halogen atoms are directly bonded to a Si atom.

In the silane coupling agent, a functional group directly bonded to a Si atom has at least one or more functional groups of alkoxy groups and halogen atoms, and from the viewpoint of ease of handling of the compound, preferably has an alkoxy group.

As the alkoxy group, an alkoxy group having 1 to 30 carbon atoms is preferable, an alkoxy group having 1 to 15 carbon atoms is more preferable, and an alkoxy group having 1 to 5 carbon atoms is particularly preferable, from the viewpoint of reactivity.

Examples of the halogen atom include an F atom, a Cl atom, a Br atom, and an I atom, and from the viewpoint of ease of synthesis and stability, a Cl atom or a Br atom is preferable, and a Cl atom is more preferable.

The silane coupling agent in the present invention preferably contains 1 to 10 silane coupling groups in the molecule, more preferably 1 to 5 silane coupling groups in the molecule, and particularly preferably 1 or 2 silane coupling groups in the molecule, from the viewpoint of favorably maintaining adhesiveness.

Specific examples of the silane coupling agent which can be applied to the present invention include vinyltrichlorosilane, vinyltrimethoxysilane, vinyltriethoxysilane, β-(3,4-epoxycyclohexyl)ethyltrimethoxysilane, γ-glycidoxypropyltrimethoxysilane, γ-glycidoxypropylmethyldiethoxysilane, γ-glycidoxypropyltriethoxysilane, γ-methacryloxypropylmethyldimethoxysilane, γ-methacryloxypropyltrimethoxysilane, γ-methacryloxypropylmethyldiethoxysilane, γ-methacryloxypropyltriethoxysilane, γ-acryloxypropyltrimethoxysilane, N-(β-aminoethyl)-γ-aminopropylmethyldimethoxysilane, N-(β-aminoethyl)-γ-aminopropyltrimethoxysilane, N-(β-aminoethyl)-γ-aminopropyltriethoxysilane, γ-aminopropyltrimethoxysilane, γ-aminopropyltriethoxysilane, N-phenyl-γ-aminopropyltrimethoxysilane, γ-mercaptopropyltrimethoxysilane, γ-chloropropyltrimethoxysilane, and γ-ureidopropyltriethoxysilane.

Examples of commercially available products thereof include KBE-503 (manufactured by Shin-Etsu Chemical Co., Ltd.).

The silane coupling agent may be used alone or in combination of two or more types thereof.

<<Surfactant>>

From the viewpoint of further improving coating property, the photosensitive resin composition of the present invention may contain a surfactant. As the surfactant, it is possible to use various types of surfactants such as fluorine-based surfactants, non-ionic surfactants, cationic surfactants, anionic surfactants, or silicone-based surfactants.

In particular, since the liquid characteristics (in particular, fluidity) at the time of preparation as a coating liquid are further improved by a fluorine surfactant being included in the photosensitive resin composition of the present invention, it is possible to further improve the uniformity of the coating thickness and the liquid-saving property.

That is, in a case where a film is formed by using a photosensitive resin composition including a fluorine-based surfactant, the wettability to the surface to be coated is improved and the coating property to the surface to be coated is improved by decreasing the interfacial tension between the surface to be coated and the coating liquid. For this reason, even in a case where a thin film having a thickness of about several μm is formed of a small amount of liquid, it is effective from the viewpoint that a film having a uniform thickness with small thickness unevenness is more suitably formed.

The fluorine content ratio in the fluorine-based surfactant is suitably 3% to 40% by mass, more preferably 5% to 30% by mass, and particularly preferably 7% to 25% by mass. The fluorine-based surfactant where the fluorine content ratio is within this range is effective from the viewpoint of the uniformity of the thickness of the coating film and the liquid-saving property, and is favorable for the dissolving property in the composition for forming a protective layer.

Examples of the fluorine-based surfactant include MEGAFAC F171, MEGAFAC F172, MEGAFAC F173, MEGAFAC F176, MEGAFAC F177, MEGAFAC F141, MEGAFAC F142, MEGAFAC F143, MEGAFAC F144, MEGAFAC R30, MEGAFAC F437, MEGAFAC F475, MEGAFAC F479, MEGAFAC F482, MEGAFAC F554, MEGAFAC F780, and MEGAFAC F781 (manufactured by DIC Corporation), FLUORAD FC430, FLUORAD FC431, and FLUORAD FC171 (manufactured by Sumitomo 3M Ltd.), SURFLON S-382, SURFLON SC-101, SURFLON SC-103, SURFLON SC-104, SURFLON SC-105, SURFLON SC1068, SURFLON SC-381, SURFLON SC-383, SURFLON S393, and SURFLON KIi-40 (manufactured by Asahi Glass Co., Ltd.), and PF636, PF656, PF6320, PF6520, and PF7002 (manufactured by OMNOVA Solutions Inc.).

Specific examples of the nonionic surfactant include glycerol, trimethylolpropane, trimethylolethane, and ethoxylates propoxylates thereof (for example, glycerol propoxylate and glycerol ethoxylate), polyoxyethylene lauryl ether, polyoxyethylene stearyl ether, polyoxyethylene oleyl ether, polyoxyethylene octyl phenyl ether, polyoxyethylene nonyl phenyl ether, polyethylene glycol dilaurate, polyethylene glycol distearate, and sorbitan fatty acid ester (PLURONIC L10, L31, L61, L62, 10R5, 17R2, 25R2, TETRONIC 304, 701, 704, 901, 904, and 150R1 manufactured by BASF SE, and SOLSPERSE 20000 (manufactured by The Lubrizol Corporation)).

Specific examples of the cationic surfactant include a phthalocyanine derivative (trade name: EFKA-745, manufactured by Morishita & Co., Ltd.), an organosiloxane polymer KP341 (manufactured by Shin-Etsu Chemical Co., Ltd.), (meth)acrylic acid-based (co)polymer POLYFLOW No. 75, No. 90, and No. 95 (manufactured by Kyoeisha Chemical Co., Ltd.), and W001 (manufactured by Yusho Co., Ltd.).

Specific examples of the anionic surfactant include W004, W005, and W017 (manufactured by Yusho Co., Ltd.).

Examples of the silicone-based surfactant include “TORAY SILICONE DC3PA”, “TORAY SILICONE SH7PA”, “TORAY SILICONE DC11PA”, “TORAY SILICONE SH21PA”, “TORAY SILICONE SH28PA”, “TORAY SILICONE SH29PA”, “TORAY SILICONE SH30PA”, and “TORAY SILICONE SH8400” manufactured by Dow Corning Toray Silicone Co., Ltd., “TSF-4440”, “TSF-4300”, “TSF-4445”, and “TSF-4460”, “TSF-4452” manufactured by Momentive Performance Materials Inc., “KP341”, “KF6001”, and “KF6002” manufactured by Shin-Etsu Chemical Co., Ltd., and “BYK307”, “BYK323”, and “BYK330” manufactured by BYK Additives & Instruments.

In a case where the resin composition of the present invention has a surfactant, the amount of the surfactant added is preferably 0.001% to 2.0% by mass, more preferably 0.005% to 1.0% by mass, with respect to the total solid content of the composition.

The surfactant may be only one type or two or more types. In a case where two or more types of surfactants are present, the total is preferably within the above range.

<<Antioxidant>>

An antioxidant may be added to the photosensitive resin composition of the present invention from the viewpoint of preventing the photosensitive resin composition from being decomposed into low molecules or being gelated due to oxidation at the time of heating. As the antioxidant, a phenol-based antioxidant, a sulfur-based antioxidant, a quinone-based antioxidant, or an amine-based antioxidant can be used.

Examples of the phenol-based antioxidant include p-methoxyphenol, 2,6-di-tert-butyl-4-methyl phenol, “Irganox1010”, “Irganox1330”, “Irganox3114”, and “Irganox1035” manufactured by BASF SE, and “Sumilizer MDP-S” and “Sumilizer GA-80” manufactured by Sumitomo Chemical Co., Ltd.

Examples of the sulfur-based antioxidant include distearyl 3,3′-thiodipropionate, and “Sumilizer TPM”, “Sumilizer TPS”, and “Sumilizer TP-D” manufactured by Sumitomo Chemical Co., Ltd.

Examples of the quinone-based antioxidant include p-benzoquinone and 2-tert-butyl-1,4-benzoquinone.

Examples of the amine-based antioxidant include dimethylaniline and phenothiazine.

Among the antioxidants described above, “Irganox1010”, “Irganox1330”, distearyl 3,3′-thiodipropionate, or “Sumilizer TP-D” is preferable, “Irganox1010” or “Irganox1330” is more preferable, and “Irganox1010” is particularly preferable.

In addition, among the antioxidants described above, a phenol-based antioxidant and a sulfur-based antioxidant are more preferably used in combination. In semiconductor processing, a processing step at a high temperature such as 220° C. is performed for a long period of time of 30 minutes or longer, and durability to the processing step is not obtained by a single antioxidant. By performing the above combination, the sulfur antioxidant absorbs the damage to be received by the phenolic antioxidant in a high temperature processing step, and thus, it is possible to prevent the deterioration of the photosensitive resin composition even in processing time for a long period of time of 30 minutes or longer. As the combination of antioxidants, a combination of “IRGANOX1010” and “SUMILIZER TP-D”, a combination of “IRGANOX1330” and “SUMILIZER TP-D”, or a combination of “SUMILIZER GA-80” and “SUMILIZER TP-D” is preferable, a combination of “IRGANOX1010” and “SUMILIZER TP-D” or a combination of “IRGANOX1330” and “SUMILIZER TP-D” is more preferable, and a combination of “IRGANOX1010” and “SUMILIZER TP-D” is particularly preferable.

The molecular weight of the antioxidant is preferably 400 or greater, more preferably 600 or greater, and particularly preferably 750 or greater, from the viewpoint of sublimination prevention during heating.

In a case where the photosensitive resin composition of the present invention has an antioxidant, the content of the antioxidant is preferably 0.001% to 20.0% by mass, and more preferably 0.005% to 10.0% by mass, with respect to the total solid content of the photosensitive resin composition. In the case of going through processing at a high temperature of 180° C. or higher, 5.0% to 10.0% by mass is particularly preferable. The antioxidant may be only one type or two or more types. In a case where two or more types of antioxidants are present, the total is preferably within the above range.

<<Ion Scavenger>>

The photosensitive resin composition of the present invention can further contain an ion scavenger to improve insulation reliability at the time of moisture absorption by adsorbing ionic impurities. The ion scavenger is not particularly limited, and examples thereof include a triazinethiol compound, a compound known as a copper inhibitor for preventing ions from being eluted by ionizing copper such as a phenol-based reductant, and inorganic compounds such as a powdery bismuth-based compound, an antimony-based compound, a magnesium-based compound, an aluminum-based compound, a zirconium-based compound, a calcium-based compound, and a titanium-based compound, a tin-based compound, and mixed compound thereof. Although the ion scavenger is not particularly limited, specific examples thereof include inorganic ion scavengers such as trade name IXE-300 (antimony-based), IXE-500 (bismuth-based), IXE-600 (antimony and bismuth-based mixed compound), IXE-700 (magnesium and aluminum-based mixed compound), IXE-800 (zirconium-based), and IXE-1100 (calcium-based) (manufactured by AGC Seimi Chemical Co., Ltd.). These can be used alone or in combination of two or more types thereof.

In a case where the photosensitive resin composition of the present invention has an ion scavenger, the content of the ion scavenger is preferably 0.01% by 10% by mass with respect to the total solid content of the photosensitive resin composition, from the viewpoint of effects by addition, heat resistance, cost, and the like.

The ion scavenger may be only one type or two or more types. In a case where two or more types of ion scavengers are present, the total is preferably within the above range.

<Preparation of Photosensitive Resin Composition>

The photosensitive resin composition of the present invention can be prepared by mixing the above respective components. The mixing method is not particularly limited, and it is possible to perform by a method known in the related art.

<Applications of Photosensitive Resin Composition>

Since the photosensitive resin composition of the present invention excellent heat resistance and excellent developability, the photosensitive resin composition can be preferably used as an underfill of a semiconductor device. In particular, the photosensitive resin composition can be preferably used as an underfill in a 3-dimensional mounting device.

<Form of Photosensitive Resin Composition>

The form of the photosensitive resin composition of the present invention may be liquid or may be sheet-shaped.

In the case of a liquid photosensitive resin composition, a solvent is preferably contained.

Examples of a sheet-shaped photosensitive resin composition include aspects shown below.

Hereinafter, the sheet-shaped photosensitive resin composition will be described with reference to drawings.

<<Sheet-Shaped Photosensitive Resin Composition>>

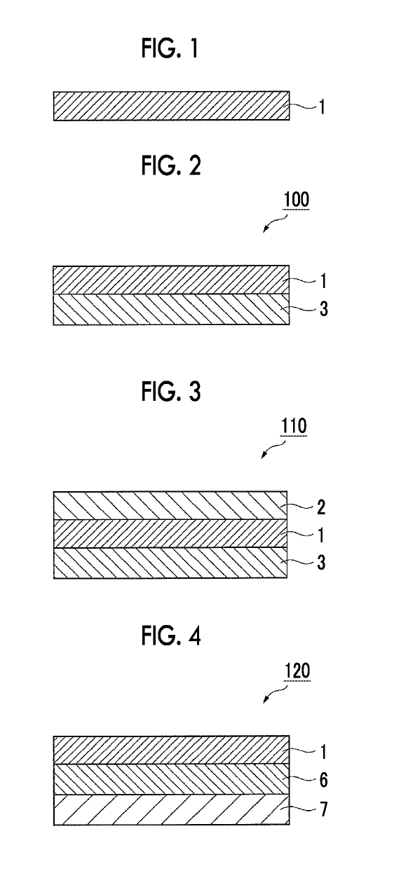

FIG. 1 is a schematic sectional view showing one embodiment of the sheet-shaped photosensitive resin composition. A sheet-shaped photosensitive resin composition (film-shaped adhesive) 1 shown in FIG. 1 is obtained by molding the photosensitive resin composition of the present invention into a film-shape.

FIG. 2 is a schematic sectional view showing one embodiment of a laminate (adhesive sheet) formed by laminating the film-shaped adhesive on the resin film. An adhesive sheet 100 shown in FIG. 2 is configured of a resin film 3 and an adhesive layer formed of a film-shaped adhesive 1 provided on one surface of the resin film 3.

FIG. 3 is a schematic sectional view showing another embodiment of the adhesive sheet. The adhesive sheet 110 shown in FIG. 3 is configured of the resin film 3, the adhesive layer formed of the film-shaped adhesive 1 provided on one surface of the resin film 3, and a cover film 2 laminated on the film-shaped adhesive 1.

The film-shaped adhesive 1 is configured of the photosensitive resin composition of the present invention. For example, the film-shaped adhesive 1 can be obtained by a method in which a maleimide-based polymer, a crosslinking agent, a photopolymerization initiator, a polymerization initiator, and the other components added as necessary are mixed in an organic solvent, the liquid mixture is kneaded to prepare varnish, a layer of the varnish is formed on the resin film 3, and after drying the varnish layer by heating, the resin film 3 is removed. At this time, without removing the resin film 3, it is also possible to store and use in the state of the adhesive sheets 100 and 110.

The mixing and kneading above can be performed by appropriately combining dispersers such as a typical stirrer, a kneader, a triple roll, and a ball mill. Drying of the varnish layer is preferably performed at a temperature at which the crosslinking agent does not sufficiently react and under a condition in which the solvent is sufficiently volatilized. Specifically, the varnish layer is preferably dried by heating at 60° C. to 180° C. for 0.1 to 90 minutes. The thickness of the varnish layer before drying is preferably 1 to 100 μm. If the thickness of the varnish layer before drying is 1 μm or greater, an adhesively fixing function is sufficiently obtained. If the thickness of the varnish layer is 100 μm or less, it is possible to reduce the residual volatile content.

A preferable residual volatile content of the varnish layer after drying is 10% by mass or less. If the residual volatile content is less than 10% by mass, voids can be less likely to occur. The measurement conditions of the residual volatile components are as follows. That is, the residual volatile content is a value when the initial mass of a film-shaped adhesive cut into a size of 50 mm×50 mm is defined as M1, the mass after the film-shaped adhesive is heated for 3 hours in an oven at 160° C. is defined as M2, and [(M2−M1)/M1]×100 is defined as the residual volatile content (%).

The temperature at which the crosslinking agent does not sufficiently react is, specifically, a temperature below the peak temperature of the heat of reaction when measured under the conditions of a sample amount of 10 mg, a temperature raising rate of 5° C./min, and a measurement atmosphere of air, using DSC (for example, “DSC-7 Model” (trade name) manufactured PerkinElmer Inc.).

The organic solvent used for preparation of the varnish, that is, a varnish solvent, is not particularly limited as long as the material can be uniformly dissolved or dispersed. The same as solvents which can be used in the photosensitive resin composition can be used. Examples thereof include dimethylformamide, toluene, benzene, xylene, methyl ethyl ketone, tetrahydrofuran, ethyl cellosolve, ethyl cellosolve acetate, dioxane, cyclohexanone, ethyl acetate, and N-methyl-pyrrolidinone.

The resin film 3 is not particularly limited as long as it withstands drying conditions. Examples thereof include a polyester film, a polypropylene film, a polyethylene terephthalate film, a polyimide film, a polyetherimide film, a polyether naphthalate film, and a methyl pentene film. The resin film 3 may be a multilayer film obtained by combining two or more types of films, or may be a film of which the surface has been treated with a silicone-based or silica-based release agent.

In the present invention, an adhesive sheet can also be made by laminating the film-shaped adhesive 1 and a dicing sheet. The dicing sheet is a sheet provided with a pressure sensitive adhesive layer on a resin film, and the pressure sensitive adhesive layer may be either a pressure sensitive type or a radiation-curable type. In addition, the above resin film is preferably an expandable resin film. By using such an adhesive sheet, a dicing die bond integrated adhesive sheet having both a function as a die bond film and a function as a dicing sheet can be obtained.

As the dicing die bond integrated adhesive sheet, specifically, as shown in FIG. 4, an adhesive sheet 120 formed by laminating a resin film 7, a pressure sensitive adhesive layer 6, and the film-shaped adhesive 1 formed of the photosensitive resin composition of the present invention in this order is exemplified.

<Laminate>

Next, the laminate of the present invention will be described.

The laminate of the present invention is a laminate having a layer formed of the photosensitive resin composition of the present invention on the semiconductor wafer surface. This laminate may be a semiconductor wafer provided with an adhesive layer.

In addition, the laminate of the present invention is also a laminate having a cured product layer formed by curing the photosensitive resin composition of the present invention on the semiconductor wafer surface. This laminate is a semiconductor device.

Hereinafter, the laminate of the present invention will be described with reference to drawings.

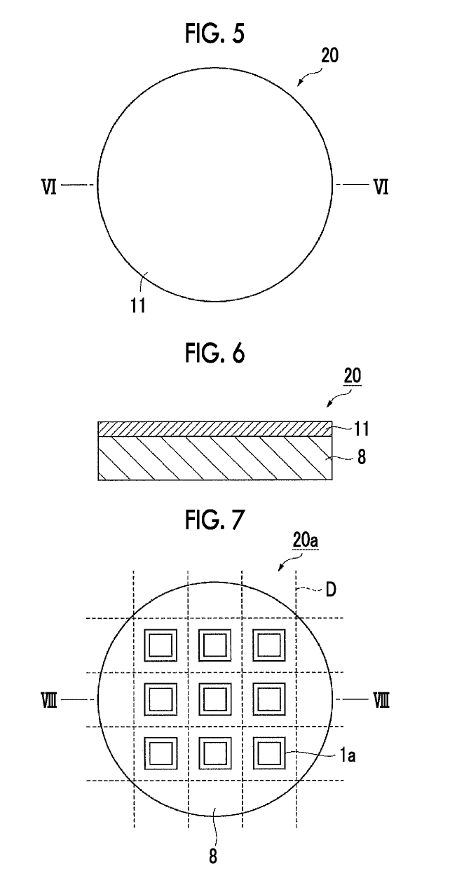

FIG. 5 is a top view showing one embodiment of a semiconductor wafer provided with an adhesive layer, and FIG. 6 is an end view taken along a line VI-VI of FIG. 5. A laminate (semiconductor wafer provided with an adhesive layer) 20 shown in FIGS. 5 and 6 has a semiconductor wafer 8 and a layer (adhesive layer) 11 formed of the photosensitive resin composition of the present invention provided on one surface of the semiconductor wafer 8.

The semiconductor wafer provided with an adhesive layer 20 is obtained by laminating a sheet-shaped photosensitive resin composition on the semiconductor wafer 8.

In addition, the semiconductor wafer provided with an adhesive layer 20 can also be obtained by applying a liquid photosensitive resin composition to the semiconductor wafer 8 and then drying the resulting product by heating at room temperature (25° C.) to 200° C. As a method of applying the photosensitive resin composition to the semiconductor wafer 8, spinning, dipping, doctor blade coating, suspended casting, coating, spraying, electrostatic spraying, and reverse roll coating are exemplified.

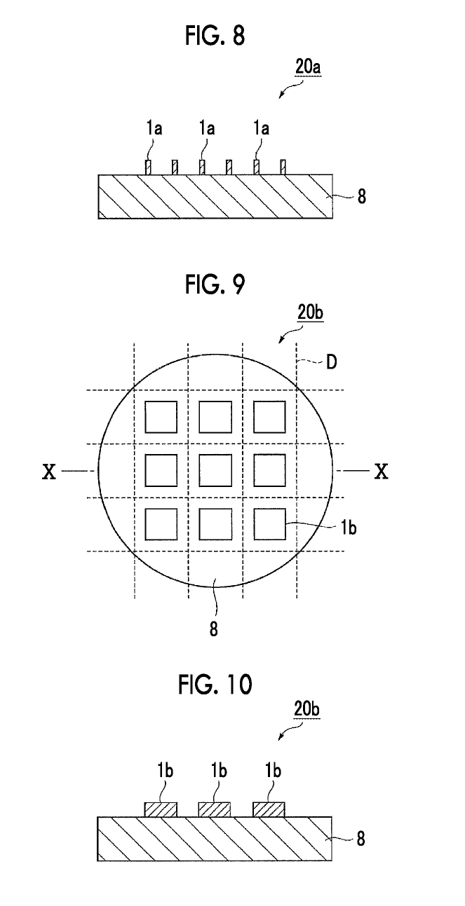

FIGS. 7 and 9 are top views showing one embodiment of the adhesive layer pattern, FIG. 8 is an end view taken along a line VIII-VIII of FIG. 7, and FIG. 10 is an end view taken along a line X-X of FIG. 9. Adhesive layer patterns 1a and 1b shown in FIGS. 7, 8, 9 and 10 are formed to have a pattern along the side of the substantially square or a square pattern on the semiconductor wafer 8 as an adherend.

The adhesive layer patterns 1a and 1b are formed by exposing an adhesive layer 11 on the semiconductor wafer provided with an adhesive layer 20 through a photomask and development-treating the adhesive layer 11 after exposure by an alkali developer. Thus, a laminate (semiconductor wafer provided with an adhesive layer 20a or 20b) in which the adhesive layer patterns 1a or 1b has been formed is obtained.

By thermal-pressing an adherend such as a semiconductor element against the adhesive layer 11 on the semiconductor wafer provided with an adhesive layer 20 and curing the adhesive layer 11, a laminate of the present invention having a cured product layer obtained by curing the photosensitive resin composition of the present invention on the surface of a semiconductor wafer can be obtained.

<Manufacturing Method for Semiconductor Device>

Next, the manufacturing method for the semiconductor device of the present invention will be described.

<<First Embodiment of Manufacturing Method for Semiconductor Device>>

The first embodiment of the manufacturing method for the semiconductor device of the present invention include a step of applying a liquid photosensitive resin composition to a semiconductor wafer, a step of drying the photosensitive resin composition applied to the semiconductor wafer, a step of exposing the dried photosensitive resin composition, a step of developing the exposed photosensitive resin composition, and a step of thermal-pressing the adherend against the surface of the developed photosensitive resin composition.

<<<Step of Applying Photosensitive Resin Composition to Semiconductor Wafer>>>

As a method of applying the photosensitive resin composition to the semiconductor wafer, spinning, dipping, doctor blade coating, suspended casting, coating, spraying, electrostatic spraying, and reverse roll coating are exemplified.

By applying the photosensitive resin composition of the present invention to a semiconductor wafer, a laminate of the present invention having a layer formed of the photosensitive resin composition of the present invention on the surface of the semiconductor wafer can be obtained.

The amount (thickness of a layer) of applying the photosensitive resin composition to a semiconductor wafer is preferably 1 to 100 μm.

After the photosensitive resin composition is applied to the semiconductor wafer, the resulting product is preferably dried. Drying is preferably performed, for example, at (25° C.) to 200° C. for 10 seconds to 30 minutes.

<<<Step of Exposing>>>

In the step of exposing, the photosensitive resin composition applied to the semiconductor wafer is irradiated with active light or radiation having a predetermined pattern. In this step, by irradiation with active light or radiation, a polymerization reaction of the crosslinking agent proceeds, and the adhesiveness in the portion irradiated with light is reduced, and thus, depending on the pattern of the mask, regions having different adhesive forces are formed.

Although the wavelength of active light or radiation varies depending on the composition of the photosensitive resin composition, the wavelength is preferably 200 to 600 nm, and more preferably 300 to 450 nm.

As the light source, a low pressure mercury lamp, a high pressure mercury lamp, an ultra-high pressure mercury lamp, a chemical lamp, an LED light source, or an excimer laser generating apparatus can be used, and active light having a wavelength of 300 nm to 450 nm such as an i-line (365 nm), a h-line (405 nm), or a g-line (436 nm) can be preferably used. In addition, it is also possible to adjust the irradiation light through a spectral filter such as a long wavelength cut filter, a short wavelength cut filter, or a band pass filter, as necessary. The exposure amount is preferably 1 to 2,000 mJ/cm².

As the exposure apparatus, it is possible to use exposure machines of various types such as a mirror projection aligner, a stepper, a scanner, proximity, contact, a micro-lens array, a lens scanner, and laser exposure.

<<<Step of Performing Development Treatment>>>

In the step of performing a development treatment, the unexposed portion of the photosensitive resin composition is developed using a developer. As the developer, an aqueous alkaline developer can be used.

Examples of the alkali compound used in the aqueous alkaline developer include sodium hydroxide, potassium hydroxide, sodium carbonate, potassium carbonate, sodium hydrogen carbonate, potassium hydrogen carbonate, sodium silicate, potassium silicate, sodium metasilicate, potassium metasilicate, ammonia, and amines. Examples of the amine include ethylamine, n-propylamine, diethylamine, di-n-propylamine, triethylamine, methyldiethylamine, alkanolamine, dimethylethanolamine, triethanolamine, quaternary ammonium hydroxide, tetramethylammonium hydroxide (TMAH), and tetraethylammonium hydroxide. Among these, an alkali compound not including a metal is preferable. A suitable aqueous alkaline developer is generally used within 0.5 N with respect to an alkali, but may be appropriately diluted before use. For example, an aqueous alkaline developer of about 0.15 to 0.4 N, preferably 0.20 to 0.35 N, is suitable.

<<<Step of Thermal-Pressing Adherend>>>

After performing the development treatment, by thermal-pressing the adherend, it is possible to manufacture a semiconductor device. Examples of the adherend include semiconductor elements.

As the thermal-pressing conditions, the heating temperature is preferably 20° C. to 250° C. The load is preferably 0.01 to 20 kgf. The heating time is preferably 0.1 to 300 seconds.

By thermal-pressing the adherend, the photosensitive resin composition is cured, and as a result, a laminate of the present invention having a cure product layer formed by curing the photosensitive resin composition of the present invention on the surface of the semiconductor wafer can be obtained.

<<Second Embodiment of Manufacturing Method for Semiconductor Device>>

The second embodiment of the manufacturing method for the semiconductor device of the present invention include a step of laminating a sheet-shaped photosensitive resin composition on a semiconductor wafer, a step of exposing the photosensitive resin composition laminated on the semiconductor wafer, a step of developing the exposed photosensitive resin composition, and a step of thermal-pressing the adherend against the surface of the developed photosensitive resin composition.

Lamination of the sheet-shaped photosensitive resin composition on a semiconductor wafer is not particularly limited, and a method of laminating the sheet-shaped photosensitive resin composition while heating the semiconductor wafer is exemplified. The heating temperature is not particularly limited, and is preferably 25° C. to 200° C. In addition, the sheet-shaped photosensitive resin composition may be laminated without being heated.

The step of exposing, the step of developing, and the step of thermal-pressing an adherend can be performed in the same manner as in the first embodiment described above.

<Semiconductor Device>

The semiconductor device using the photosensitive resin composition of the present invention as an underfill will be specifically described using drawings. In recent years, semiconductor devices having various structures have been proposed, and the applications of the photosensitive resin composition of the present invention as an underfill are not limited to a semiconductor device having a structure described below.

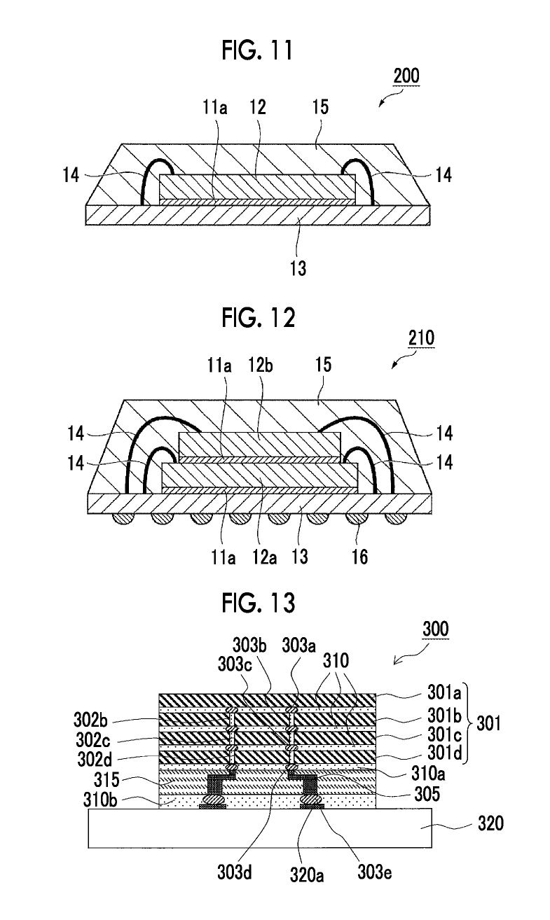

FIG. 11 is a schematic sectional view showing one embodiment of the semiconductor device of the present invention. In a semiconductor device 200 shown in FIG. 11, a semiconductor element 12 is adhered to a support member 13 for mounting a semiconductor element through an underfill layer 11a formed of the photosensitive resin composition of the present invention, and a connection terminal (not shown) of the semiconductor element 12 is electrically connected to an external connection terminal (not shown) through wires 14 and is sealed with a sealing material 15.

In addition, FIG. 12 is a schematic sectional view showing another embodiment of the semiconductor device of the present invention. In a semiconductor device 210 shown in FIG. 12, a semiconductor element 12a of the first stage is adhered to the support member 13 for mounting a semiconductor element on which a terminal 16 is formed, through the underfill layer 11a, and a semiconductor element 12b of the second stage is further adhered to the semiconductor element 12a of the first stage through the underfill layer 11a. The connection terminals (not shown) of the semiconductor element 12a of the first stage and the semiconductor element 12b of the second stage are electrically connected to external connection terminals through the wires 14 and are sealed with a sealing material 15. Thus, the photosensitive resin composition of the present invention can be suitably used in semiconductor device having a structure in which a plurality of semiconductor elements are stacked.

The semiconductor devices (semiconductor package) 200 and 210 shown in FIGS. 11 and 12 can be obtained, for example, by dicing the semiconductor wafer provided with an adhesive layer 20b shown in FIG. 9 along the broken line D, by thermal-pressing the semiconductor element provided with an adhesive layer after dicing against the support member 13 for mounting a semiconductor element to bond both, and by going through a wire bonding step and as necessary, a step such as a step of sealing with a sealing material. The heating temperature in thermal-pressing is preferably 20° C. to 250° C. The load is preferably 0.01 to 20 kgf. The heating time is preferably 0.1 to 300 seconds.

FIG. 13 is a schematic sectional view showing another embodiment of the semiconductor device of the present invention.

A semiconductor device 300 shown in FIG. 13 is a so-called 3-dimensional mounting device, and a semiconductor element laminate 301 in which a plurality of semiconductor elements 301a to 301d are laminated is disposed on the support member 320 for mounting a semiconductor element.

In this embodiment, although a case in which the laminating number of semiconductor elements is 4 layers is described mainly, the laminating number of semiconductor elements is not particularly limited, and for example, the laminating number may be 2 layers, 8 layers, 16 layers, or 32 layers. In addition, the laminating number may be a single layer.

301a to 301d are all formed of a semiconductor wafer such as a silicon substrate.

The semiconductor element 301a placed at the top does not have a through-hole electrode, and an electrode pad (not shown) is formed on one surface thereof.

Semiconductor elements 301b to 301d have through-hole electrodes 302b to 302d, and on both surfaces of each semiconductor element, a connection pad (not shown) provided integrally with the through-hole electrode is provided.

The semiconductor element laminate 301 has a structure in which the semiconductor element 301a having no through-hole electrode and the semiconductor elements 301b to 301d having the through-hole electrodes 302b to 302d are flip-chip-connected.

That is, an electrode pad of the semiconductor element 301a having no through-hole electrode and a connection pad on the semiconductor element 301a side of the semiconductor element 301b having the through-hole electrode 302b adjacent thereto are connected by a metal bump 303a such as a solder bump, and a connection pad on the other side of the semiconductor element 301b having a through-hole electrode 302b is connected by a connection pad on the semiconductor element 301b side of the semiconductor element 301c having a through-hole electrode 302c adjacent thereto and a metal bump 303b such as a solder bump. In the same manner, a connection pad on the other side of the semiconductor element 301c having the through-hole electrode 302c is connected by a connection pad on the semiconductor element 301c side of a semiconductor element 301d having a through-hole electrode 302d adjacent thereto and a metal bump 303c such as a solder bump.

In each gap among the semiconductor elements 301a to 301d, an underfill layer 310 is formed, and each of the semiconductor elements 301a to 301d is laminated through the underfill layer 310. The underfill layer 310 is formed using the photosensitive resin composition of the present invention.

The semiconductor element laminate 301 is laminated on the support member 320 for mounting a semiconductor element.

As the support member 320 for mounting a semiconductor element, for example, a multilayer wiring substrate using an insulating substrate such as a resin substrate, a ceramic substrate, or a glass substrate as a substrate is used. As the support member 320 for mounting a semiconductor element to which the resin substrate is applied, a multilayer copper-clad laminated board (multilayer printed wiring board) is exemplified.

A surface electrode 320a is provided on one surface of the support member 320 for mounting a semiconductor element.

Between the support member 320 for mounting a semiconductor element and the semiconductor element laminate 301, an insulating layer 315 in which a rewiring layer 305 is formed is disposed, and the support member 320 for mounting a semiconductor element and the semiconductor element laminate 301 is electrically connected through the rewiring layer 305.

That is, one end of the rewiring layer 305 is connected to an electrode pad formed on the surface of the semiconductor element 301d on the rewiring layer 305 side through a metal bump 303d such as a solder bump. The other end of the rewiring layer 305 is connected to the surface electrode 320a of the support member for mounting a semiconductor element through a metal bump 303e such as a solder bump.

Between the insulating layer 315 and the semiconductor element laminate 301, an underfill layer 310a is formed. In addition, between the insulating layer 315 and the support member 320 for mounting a semiconductor element, an underfill layer 310b is formed. The underfill layers 310a and 310b are formed of the photosensitive resin composition of the present invention.

### EXAMPLES

Hereinafter, the present invention will be further specifically described with reference to examples, but the present invention is not limited to the following examples as long as it does not depart from the scope thereof. Moreover, “%” and “parts” are based on mass unless specified otherwise.

### Synthesis Example 1

### Synthesis of Maleimide-Based Polymer (a-1)

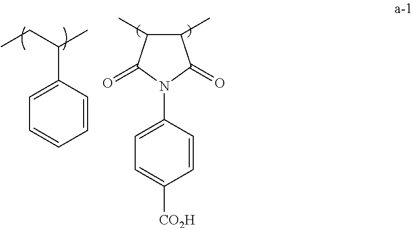

Into a three-neck flask provided with a stirring blade, a reflux condenser, and a thermometer, SMA3000 (manufactured by Cray Valley, 8.21 g), p-aminobenzoic acid (manufactured by Wako Pure Chemical Industries, Ltd., 2.88 g), and N,N-dimethylacetamide (manufactured by Wako Pure Chemical Industries, Ltd., 35 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-1 was obtained. The structure of the obtained a-1 was identified by ¹H NMR. When Mw of a-1 was measured by GPC, Mw was 13,000 in terms of polystyrene.

### Synthesis Example 2

### Synthesis of Maleimide-Based Polymer (a-2)

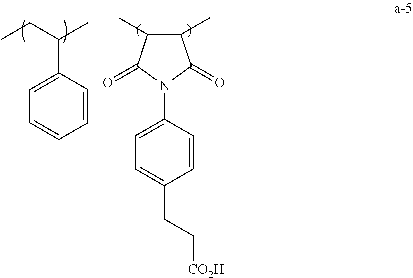

Into a three-neck flask provided with a stirring blade, a reflux condenser, and a thermometer, ZeMac E60 (manufactured by Vertellus Specialties Inc., 6.31 g), p-aminobenzoic acid (manufactured by Wako Pure Chemical Industries, Ltd., 7.54 g), and N,N-dimethylacetamide (manufactured by Wako Pure Chemical Industries, Ltd., 40 g) were put, and the resulting product was stirred at 80° C. for 1 hour. Next, acetic acid (manufactured by Wako Pure Chemical Industries, Ltd., 25.04 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-2 was obtained. The structure of the obtained a-2 was identified by ¹H NMR. When Mw of a-2 was measured by GPC, Mw was 70,000 in terms of polystyrene.

### Synthesis Example 3

### Synthesis of Maleimide-Based Polymer (a-3)

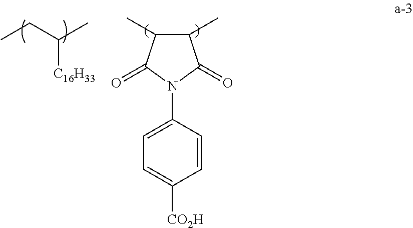

Into a three-neck flask provided with a stirring blade, a reflux condenser, and a thermometer, poly(maleic acid anhydride-alt-1-octadecene) (manufactured by Sigma-Aldrich Co. LLC., 17.92 g), p-aminobenzoic acid (manufactured by Wako Pure Chemical Industries, Ltd., 7.54 g), and N,N-dimethylacetamide (manufactured by Wako Pure Chemical Industries, Ltd., 40 g) were put, and the resulting product was stirred at 80° C. for 1 hour. Next, acetic acid (manufactured by Wako Pure Chemical Industries, Ltd., 25.04 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-3 was obtained. The structure of the obtained a-3 was identified by ¹H NMR. When Mw of a-3 was measured by GPC, Mw was 50,000 in terms of polystyrene.

### Synthesis Example 4

### Synthesis of Maleimide-Based Polymer (a-4)

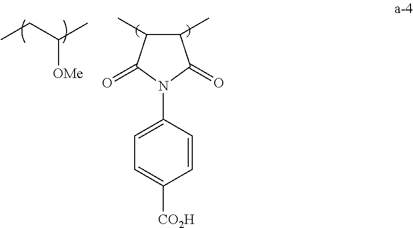

Into a three-neck flask provided with a stirring blade, a reflux condenser, and a thermometer, poly(methyl vinyl ether-alt-maleic acid anhydride) (manufactured by Sigma-Aldrich Co. LLC., 8.51 g), p-aminobenzoic acid (manufactured by Wako Pure Chemical Industries, Ltd., 7.54 g), and N,N-dimethylacetamide (manufactured by Wako Pure Chemical Industries, Ltd., 40 g) were put, and the resulting product was stirred at 80° C. for 1 hour. Next, acetic acid (manufactured by Wako Pure Chemical Industries, Ltd., 25.04 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-4 was obtained. The structure of the obtained a-4 was identified by ¹H NMR. When Mw of a-4 was measured by GPC, Mw was 230,000 in terms of polystyrene.

### Synthesis Example 5

### Synthesis of Maleimide-Based Polymer (a-5)

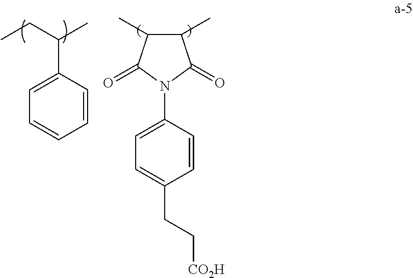

Into a three-neck flask provided with a stirring blade, a reflux condenser, and a thermometer, SMA3000 (manufactured by Cray Valley, 8.21 g), 3-alanine (manufactured by Tokyo Chemical Industry Co., Ltd., 1.87 g), and N,N-dimethylacetamide (manufactured by Wako Pure Chemical Industries, Ltd., 35 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-5 was obtained. The structure of the obtained a-5 was identified by ¹H NMR. When Mw of a-5 was measured by GPC, Mw was 11,000 in terms of polystyrene.

### Synthesis Example 6

### Synthesis of Maleimide-Based Polymer (a-6)

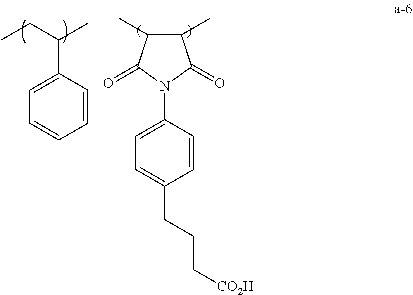

Into a three-neck flask provided with a stirring blade, a reflux condenser, and a thermometer, SMA3000 (manufactured by Cray Valley, 8.21 g), 4-aminobutanoic acid (manufactured by Tokyo Chemical Industry Co., Ltd., 2.17 g), and N,N-dimethylacetamide (manufactured by Wako Pure Chemical Industries, Ltd., 35 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-6 was obtained. The structure of the obtained a-6 was identified by ¹H NMR. When Mw of a-6 was measured by GPC, Mw was 12,000 in terms of polystyrene.

### Synthesis Example 7

### Synthesis of Maleimide-Based Polymer (a-7)

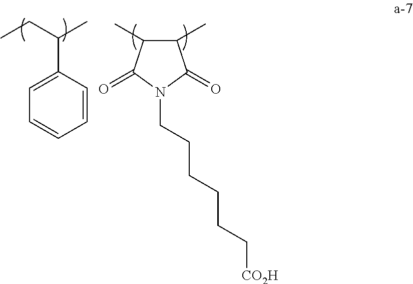

Into a three-neck flask provided with a stirring blade, a reflux condenser, and a thermometer, SMA3000 (manufactured by Cray Valley, 8.21 g), 7-aminoheptanoic acid (manufactured by Tokyo Chemical Industry Co., Ltd., 3.05 g), and N,N-dimethylacetamide (manufactured by Wako Pure Chemical Industries, Ltd., 35 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-7 was obtained. The structure of the obtained a-7 was identified by ¹H NMR. When Mw of a-7 was measured by GPC, Mw was 14,000 in terms of polystyrene.

### Synthesis Example 8

### Synthesis of Maleimide-Based Polymer (a-8)

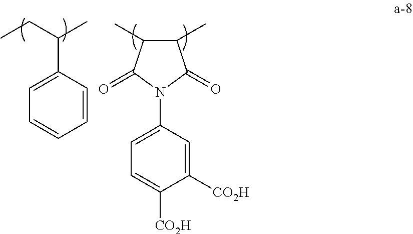

Into a three-neck flask provided with a stirring blade, a reflux condenser, and a thermometer, SMA3000 (manufactured by Cray Valley, 8.21 g), 4-aminophthalic acid (manufactured by Tokyo Chemical Industry Co., Ltd., 3.80 g), and N,N-dimethylacetamide (manufactured by Wako Pure Chemical Industries, Ltd., 35 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-8 was obtained. The structure of the obtained a-8 was identified by ¹H NMR. When Mw of a-8 was measured by GPC, Mw was 14,000 in terms of polystyrene.

### Synthesis Example 9

### Synthesis of Maleimide-Based Polymer (a-9)

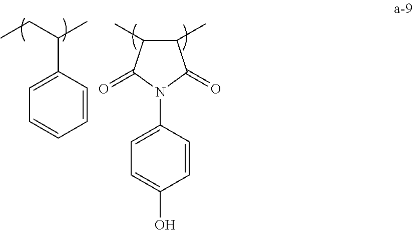

Into a three-neck flask provided with a stirring blade, a reflux condenser, and a thermometer, SMA3000 (manufactured by Cray Valley, 8.21 g), 4-aminophenol (manufactured by Tokyo Chemical Industry Co., Ltd., 2.29 g), and N,N-dimethylacetamide (manufactured by Wako Pure Chemical Industries, Ltd., 35 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-9 was obtained. The structure of the obtained a-9 was identified by ¹H NMR. When Mw of a-9 was measured by GPC, Mw was 12,000 in terms of polystyrene.

### Synthesis Example 10

### Synthesis of Maleimide-Based Polymer (a-10)

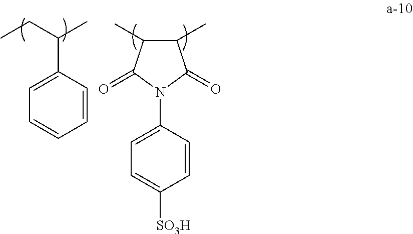

Into a three-neck flask provided with a stirring blade, a reflux condenser, and a thermometer, SMA3000 (manufactured by Cray Valley, 8.21 g), sulfanilic acid (manufactured by Tokyo Chemical Industry Co., Ltd., 3.64 g), and N,N-dimethylacetamide (manufactured by Wako Pure Chemical Industries, Ltd., 35 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-10 was obtained. The structure of the obtained a-10 was identified by ¹H NMR. When Mw of a-10 was measured by GPC, Mw was 14,000 in terms of polystyrene.

### Synthesis Example 11

### Synthesis of Maleimide-Based Polymer (a-1-2)

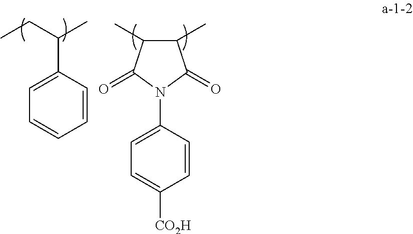

Into a three-neck flask provided with a stirring blade, a reflux condenser, and a thermometer, SMA1000 (manufactured by Cray Valley, 10.11 g), p-aminobenzoic acid (manufactured by Wako Pure Chemical Industries, Ltd., 5.67 g), and N,N-dimethylacetamide (manufactured by Wako Pure Chemical Industries, Ltd., 50 g) were put, and the resulting product was stirred at 80° C. for 1 hour. Next, acetic acid (manufactured by Wako Pure Chemical Industries, Ltd., 25.04 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-1-2 was obtained. The structure of the obtained a-1-2 was identified by ¹H NMR. When Mw of a-1-2 was measured by GPC, Mw was 6,800 in terms of polystyrene.

### Synthesis Example 12

### Synthesis of Maleimide-Based Polymer (a-1-3)

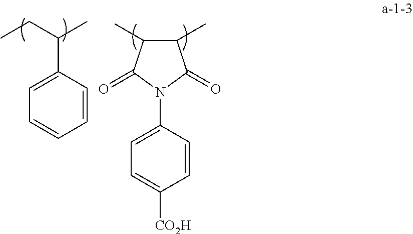

Into a three-neck flask provided with a stirring blade, a reflux condenser, and a thermometer, SMA2000 (manufactured by Cray Valley, 6.13 g), p-aminobenzoic acid (manufactured by Wako Pure Chemical Industries, Ltd., 2.88 g), and N,N-dimethylacetamide (manufactured by Wako Pure Chemical Industries, Ltd., 30 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-1-3 was obtained. The structure of the obtained a-1-3 was identified by ¹H NMR. When Mw of a-1-3 was measured by GPC, Mw was 9,200 in terms of polystyrene.

### Synthesis Example 13

### Synthesis of Maleimide-Based Polymer (a-1-4)

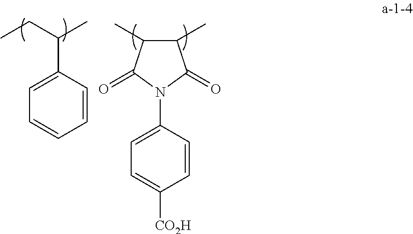

Into a three-neck flask provided with a stirring blade, a reflux condenser, and a thermometer, SMA2021 (manufactured by Cray Valley, 6.13 g), p-aminobenzoic acid (manufactured by Wako Pure Chemical Industries, Ltd., 2.88 g), and N,N-dimethylacetamide (manufactured by Wako Pure Chemical Industries, Ltd., 30 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-1-4 was obtained. The structure of the obtained a-1-4 was identified by ¹H NMR. When Mw of a-1-4 was measured by GPC, Mw was 30,000 in terms of polystyrene.

### Synthesis Example 14

### Synthesis of Maleimide-Based Polymer (a-1-5)

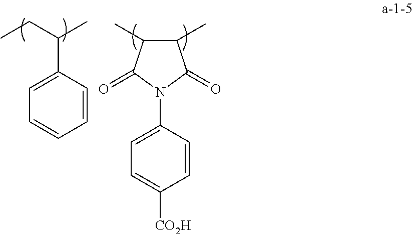

Into a three-neck flask provided with a stirring blade, a reflux condenser, and a thermometer, SMA E40 (manufactured by Cray Valley, 6.13 g), p-aminobenzoic acid (manufactured by Wako Pure Chemical Industries, Ltd., 1.80 g), and N,N-dimethylacetamide (manufactured by Wako Pure Chemical Industries, Ltd., 30 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-1-5 was obtained. The structure of the obtained a-1-5 was identified by ¹H NMR. When Mw of a-1-5 was measured by GPC, Mw was 30,000 in terms of polystyrene.

### Synthesis Example 15

### Synthesis of Maleimide-Based Polymer (a-1-6)

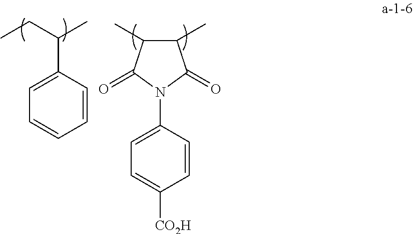

Into a three-neck flask provided with a stirring blade, a reflux condenser, and a thermometer, SMA E60 (manufactured by Cray Valley, 6.13 g), p-aminobenzoic acid (manufactured by Wako Pure Chemical Industries, Ltd., 1.28 g), and N,N-dimethylacetamide (manufactured by Wako Pure Chemical Industries, Ltd., 30 g) were put, and the resulting product was stirred at 80° C. for 1 hour. Next, acetic acid (manufactured by Wako Pure Chemical Industries, Ltd., 10.03 g) was added thereto, and the resulting product was stirred at 120° C. for 9 hours. The obtained solution was cooled to room temperature, and was added dropwise to methanol/water (50/50 (mass ratio)). The precipitated solid was collected by filtration, and dried using a vacuum dryer, whereby a-1-6 was obtained. The structure of the obtained a-1-6 was identified by ¹H NMR. When Mw of a-1-6 was measured by GPC, Mw was 30,000 in terms of polystyrene.

### Synthesis Example 16

### Synthesis of Polyimide (p-1)

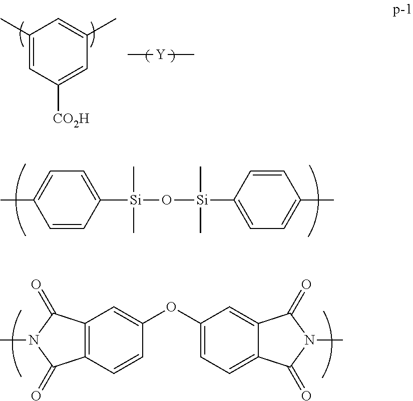

Into a three-neck flask provided with a stirring blade, a reflux condenser, and a thermometer, 3,5-diaminobenzoic acid (manufactured by Tokyo Chemical Industry Co., Ltd., 1.89 g), aliphatic ether diamine D-400 (manufactured by BASF SE, 15.21 g), 1,1,3,3-tetramethyl-1,3-bis(4-aminophenyl)disiloxane LP-7100 (manufactured by Shin-Etsu Chemical Co., Ltd., 0.39 g), and N-methyl-2-pyrrolidinone (manufactured by Wako Pure Chemical Industries, Ltd., 116 g) were put. Next, 4,4′-oxydiphthalic acid dianhydride (manufactured by Wako Pure Chemical Industries, Ltd., 16.88 g) was added little by little into the flask while cooling the flask in an ice bath. After the addition ended, the resulting product was further stirred at room temperature for 5 hours. Next, the flask was provided with a reflux condenser with a moisture receptor, 70 g of xylene was added thereto, then, while blowing nitrogen gas thereinto, the temperature was raised to 180° C. and maintained for 5 hours, and water and xylene were azeotropically removed. The obtained solution was cooled to room temperature, and was added dropwise to distilled water. The precipitated solid was collected by filtration, and dried using a vacuum dryer, whereby p-1 was obtained. The structure of the obtained p-1 was identified by ¹H NMR. When Mw of p-1 was measured by GPC, Mw was 33,000 in terms of polystyrene. Moreover, “Y” in the above structural formula represents polyether.

### Synthesis Example 17

### Synthesis of Acrylic Acid-Phenyl Maleimide Copolymer (p-3)

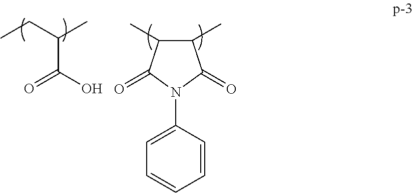

Into a three-neck flask provided with a stirring blade, a reflux condenser, and a thermometer, acrylic acid (manufactured by Wako Pure Chemical Industries, Ltd., 7.21 g), N-phenylmaleimide (manufactured by Tokyo Chemical Industry Co., Ltd., 17.32 g), and N,N-dimethylformamide (manufactured by Wako Pure Chemical Industries, Ltd., 82 g) were put, and the resulting product was homogeneously dissolved at room temperature. Next, azobisisobutyronitrile (AIBN) (manufactured by Wako Pure Chemical Industries, Ltd., 1.64 g) was added thereto. While blowing nitrogen gas thereinto, the temperature was raised to 70° C., and stirring was performed for 6 hours. The obtained solution was cooled to room temperature, and was added dropwise to distilled water. The precipitated solid was collected by filtration, and dried using a vacuum dryer, whereby p-3 was obtained. The structure of the obtained p-3 was identified by ¹H NMR. When Mw of p-3 was measured by GPC, Mw was 30,000 in terms of polystyrene.

### Synthesis Example 18

### Synthesis of p-Hydroxystyrene-Phenyl Maleimide Copolymer (p-4)

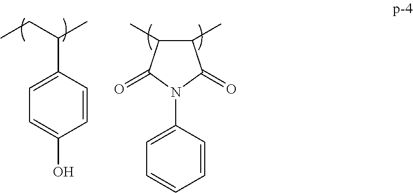

Into a three-neck flask provided with a stirring blade, a reflux condenser, and a thermometer, p-(tert)-butoxy)styrene (manufactured by Wako Pure Chemical Industries, Ltd., 9.75 g), N-phenylmaleimide (manufactured by Tokyo Chemical Industry Co., Ltd., 9.52 g), and N,N-dimethylformamide (manufactured by Wako Pure Chemical Industries, Ltd., 50 g) were put, and the resulting product was homogeneously dissolved at room temperature. Next, azobisisobutyronitrile (AIBN) (manufactured by Wako Pure Chemical Industries, Ltd., 0.13 g) was added thereto. While blowing nitrogen gas thereinto, the temperature was raised to 70° C., and stirring was performed for 6 hours. Next, concentrated hydrochloric acid (manufactured by Wako Pure Chemical Industries, Ltd., 6.20 g) was added thereto, and further heated at 70° C. for 3 hours. The obtained solution was cooled to room temperature, and was added dropwise to distilled water. The precipitated solid was collected by filtration, and dried using a vacuum dryer, whereby p-4 was obtained. The structure of the obtained p-4 was identified by ¹H NMR. When Mw of p-4 was measured by GPC, Mw was 20,000 in terms of polystyrene.

### Examples 1 to 46 and Comparative Examples 1 to 7

By mixing the following components, liquid photosensitive resin compositions were prepared.

In Example 37, the content of the photopolymerization initiator was 0.5 parts by weight. In Example 38, the content of the photopolymerization initiator was 0.2 parts by weight. In Example 39, the content of the thermal polymerization initiator was 0.2 parts by weight. In addition, in Example 40, the content of the photopolymerization initiator was 0.1 parts by weight.

<Composition of Photosensitive Resin Composition>
(a) Polymer: 75 parts by mass
(b) Crosslinking agent: 25 parts by mass
(c) Photopolymerization initiator: 2 parts by mass
(d) Solvent: 160 parts by mass
(e) Thermal polymerization initiator: 1 part by mass
(f) Filler: 10 parts by mass
(g) Adhesiveness-imparting agent: 5 parts by mass

<Weight Loss Amount of Polymer at 300° C.>

The temperature of each polymer was raised to 500° C. at a temperature raising rate of 20° C./min under a nitrogen stream using a thermal analysis equipment (TGA) (Q500, manufactured by TA Instruments), and the weight loss ratio at 300° C. was determined.

<Evaluation of Heat Resistance>

Each photosensitive resin composition was applied to a silicon wafer (diameter of 4 inches, thickness of 525 m) by spin coating such that the film thickness after drying became 20 μm, and heated at 140° C. for 5 minutes. Next, the resulting product was exposed at 1,000 mJ/cm² (wavelength: 365 nm) using a parallel exposure device to be cured. The temperature of the resulting product was raised to 500° C. at a temperature raising rate of 20° C./min under a nitrogen stream using a thermal analysis equipment (TGA) (Q500, manufactured by TA Instruments), and the weight loss ratio at 300° C. was determined. The heat resistance was evaluated according to the following criteria. In the following criteria, 2 to 5 were practical, 3 to 5 were preferable, and 4 and 5 were particularly preferable.

5: Weight loss ratio was less than 1%

4: Weight loss ratio was 1% or greater and less than 5%

3: Weight loss ratio was 5% or greater and less than 10%

2: Weight loss ratio was 10% or greater and less than 15%

1: Weight loss ratio 15% or greater

<Evaluation of Developability>

Each photosensitive resin composition was applied to a silicon wafer (diameter of 4 inches, thickness of 525 μm) by spin coating such that the film thickness after drying became 20 μm, and heated at 140° C. for 5 minutes. Next, the resulting product was exposed at 1,000 mJ/cm² (wavelength: 365 nm) using a parallel exposure device, through a mask in which dots having a diameter of 50 μm had been disposed. Next, the resulting product was immersed in a 2.38% by weight aqueous solution of tetramethylammonium hydroxide for 1 minute, and washed with water to be developed. The hole pattern after the development was observed using an optical microscope, and the developability was evaluated according to the following criteria. In the following criteria, 3 to 5 were practical, and 4 and 5 were particularly preferable.

5: A residual film was not present, and a hole pattern was obtained

4: A residual film was present at less than 50%, but a hole pattern was obtained

3: A residual film was present at 50% or greater, but a hole pattern was obtained

2: A pattern was formed, but the most part was hardly developed.

1: A pattern was not formed at all

<Evaluation of Curability>

Each photosensitive resin composition was applied to a silicon wafer (diameter of 4 inches, thickness of 525 μm) by spin coating such that the film thickness after drying became 20 μm, and heated at 140° C. for 5 minutes. Next, the resulting product was exposed at 1,000 mJ/cm² (wavelength: 365 nm) using a parallel exposure device to be semi-cured. Next, after heating to 180° C. on a hot plate and rubbing the surface with a spatula, the time until traces does not occur was measured. The curability was evaluated according to the following criteria. In the following criteria, 2 to 5 were practical, 3 to 5 were preferable, and 4 and 5 were particularly preferable.

5: traces did not occur within 5 minutes

4: traces did not occur within a range of longer than 5 minutes to 10 minutes

3: traces did not occur within a range of longer than 10 minutes to 15 minutes

2: traces did not occur within a range of longer than 15 minutes to 20 minutes

1: longer than 20 minutes until traces did not occur

TABLE 1

| | | | | | | | | | (g) | | | |
|---|---|---|---|---|---|---|---|---|---|---|---|---|
| | (a) Polymer | | | (b) | (c) | | | | Adhesive- | | | |
| | | | Weight loss | Cross- | Photopoly- | (d) | (e) Thermal | | ness- | Evaluation results | | |
| | | Acid | ratio at | linking | merization | Sol- | polymerization | (f) | imparting | | Heat | |
| | | value | 300° C. | agent | initiator | vent | initiator | Filler | agent | Developa- | resis- | Cura- |
| | Name | mgKOH | (%) | Name | Name | Name | Name | Name | Name | bility | tance | bility |
| Example 1 | a-1 | 105 | 1 or less | b-1 | c-1 | GBL | e-1 | f-1 | g-1 | 5 | 5 | 5 |
| Example 2 | a-2 | 228 | 3 | b-1 | c-1 | GBL | e-1 | f-1 | g-1 | 5 | 4 | 5 |
| Example 3 | a-3 | 119 | 5 | b-1 | c-1 | GBL | e-1 | f-1 | g-1 | 4 | 3 | 5 |
| Example 4 | a-4 | 203 | 10 | b-1 | c-1 | GBL | e-1 | f-1 | g-1 | 5 | 2 | 5 |
| Example 5 | a-5 | 116 | 5 | b-1 | c-1 | GBL | e-1 | f-1 | g-1 | 5 | 3 | 5 |
| Example 6 | a-6 | 113 | 5 | b-1 | c-1 | GBL | e-1 | f-1 | g-1 | 5 | 3 | 5 |
| Example 7 | a-7 | 104 | 5 | b-1 | c-1 | GBL | e-1 | f-1 | g-1 | 5 | 3 | 5 |
| Example 8 | a-8 | 195 | 1 or less | b-1 | c-1 | GBL | e-1 | f-1 | g-1 | 5 | 5 | 5 |
| Example 9 | a-9 | 112 | 1 or less | b-1 | c-1 | GBL | e-1 | f-1 | g-1 | 3 | 5 | 5 |
| Example 10 | a-10 | 198 | 1 or less | b-1 | c-1 | GBL | e-1 | f-1 | g-1 | 5 | 5 | 5 |
| Example 11 | a-1-2 | 174 | 1 or less | b-1 | c-1 | GBL | e-1 | f-1 | g-1 | 5 | 5 | 5 |
| Example 12 | a-1-3 | 132 | 1 or less | b-1 | c-1 | GBL | e-1 | f-1 | g-1 | 5 | 5 | 5 |
| Example 13 | a-1-4 | 132 | 1 or less | b-1 | c-1 | GBL | e-1 | f-1 | g-1 | 5 | 5 | 5 |
| Example 14 | a-1-5 | 88 | 1 or less | b-1 | c-1 | GBL | e-1 | f-1 | g-1 | 4 | 5 | 5 |
| Example 15 | a-1-6 | 66 | 1 or less | b-1 | c-1 | GBL | e-1 | f-1 | g-1 | 3 | 5 | 5 |
| Example 16 | a-1 | 105 | 1 or less | b-2 | c-1 | GBL | e-1 | f-1 | g-1 | 4 | 5 | 5 |
| Example 17 | a-1 | 105 | 1 or less | b-3 | c-1 | GBL | e-1 | f-1 | g-1 | 4 | 5 | 5 |
| Example 18 | a-1 | 105 | 1 or less | b-4 | c-1 | GBL | e-1 | f-1 | g-1 | 4 | 5 | 5 |
| Example 19 | a-1 | 105 | 1 or less | b-5 | c-1 | GBL | e-1 | f-1 | g-1 | 4 | 5 | 5 |
| Example 20 | a-1 | 105 | 1 or less | b-6 | c-1 | GBL | e-1 | f-1 | g-1 | 4 | 5 | 5 |
| Example 21 | a-1 | 105 | 1 or less | b-7 | c-1 | GBL | e-1 | f-1 | g-1 | 5 | 2 | 5 |
| Example 22 | a-1 | 105 | 1 or less | b-1/b-8*¹ | c-1 | GBL | e-1 | f-1 | g-1 | 4 | 3 | 4 |
| Example 23 | a-1 | 105 | 1 or less | b-1/b-8*¹ | c-1 | GBL | e-12 | f-1 | g-1 | 4 | 3 | 2 |
| Example 24 | a-1 | 105 | 1 or less | b-1 | c-1 | GBL | e-1 | f-1 | — | 5 | 5 | 5 |
| Example 25 | a-1 | 105 | 1 or less | b-1 | c-1 | GBL | e-1 | f-2 | g-1 | 5 | 5 | 5 |
| Example 26 | a-1 | 105 | 1 or less | b-1 | c-1 | GBL | e-1 | f-1 | g-1 | 5 | 5 | 5 |
| Example 27 | a-1 | 105 | 1 or less | b-1 | c-2 | GBL | e-1 | f-1 | g-1 | 5 | 5 | 5 |
| Example 28 | a-1 | 105 | 1 or less | b-1 | c-3 | GBL | e-1 | f-1 | g-1 | 5 | 5 | 5 |
| Example 29 | a-1 | 105 | 1 or less | b-1 | c-4 | GBL | e-1 | f-1 | g-1 | 5 | 5 | 5 |
| Example 30 | a-1 | 105 | 1 or less | b-1 | c-1 | GBL | e-2 | f-1 | g-1 | 4 | 5 | 5 |
| Example 31 | a-1 | 105 | 1 or less | b-1 | c-1 | GBL | e-3 | f-1 | g-1 | 5 | 5 | 5 |
| Example 32 | a-1 | 105 | 1 or less | b-1 | c-1 | GBL | e-4 | f-1 | g-1 | 5 | 5 | 5 |
| Example 33 | a-1 | 105 | 1 or less | b-1 | c-1 | GBL | e-5 | f-1 | g-1 | 5 | 5 | 3 |
| Example 34 | a-1 | 105 | 1 or less | b-1 | c-1 | GBL | e-6 | f-1 | g-1 | 5 | 5 | 5 |
| Example 35 | a-1 | 105 | 1 or less | b-1 | c-1 | GBL | e-7 | f-1 | g-1 | 5 | 5 | 4 |
| Example 36 | a-1 | 105 | 1 or less | b-1 | c-1 | GBL | e-8 | f-1 | g-1 | 5 | 5 | 5 |
| Example 37 | a-1 | 105 | 1 or less | b-1 | c-1 | GBL | e-1 | f-1 | g-1 | 5 | 5 | 5 |
| | | | | | (0.5 parts | | | | | | | |
| | | | | | by mass) | | | | | | | |
| Example 38 | a-1 | 105 | 1 or less | b-1 | c-1 | GBL | e-1 | f-1 | g-1 | 4 | 5 | 5 |
| | | | | | (0.2 parts | | | | | | | |
| | | | | | by mass) | | | | | | | |
| Example 39 | a-1 | 105 | 1 or less | b-1 | c-1 | GBL | e-1 | f-1 | g-1 | 5 | 5 | 4 |
| | | | | | | | (0.2 parts | | | | | |
| | | | | | | | by mass) | | | | | |
| Example 40 | a-1 | 105 | 1 or less | b-1 | c-1 | GBL | e-1 | f-1 | g-1 | 5 | 5 | 3 |
| | | | | | | | (0.1 parts | | | | | |
| | | | | | | | by mass) | | | | | |
| Example 41 | a-1 | 105 | 1 or less | b-1 | c-1 | GBL | e-9 | f-1 | g-1 | 5 | 5 | 4 |
| Example 42 | a-1 | 105 | 1 or less | b-1 | c-1 | GBL | e-10 | f-1 | g-1 | 3 | 5 | 5 |
| Example 43 | a-1 | 105 | 1 or less | b-1 | c-1 | GBL | e-11 | f-1 | g-1 | 5 | 5 | 3 |
| Example 44 | a-1 | 105 | 1 or less | b-1/b-2*² | c-1 | GBL | e-1 | f-1 | g-1 | 5 | 5 | 5 |
| Example 45 | a-1 | 105 | 1 or less | b-1 | c-1/c-3*³ | GBL | e-1 | f-1 | g-1 | 5 | 5 | 5 |
| Example 46 | a-1 | 105 | 1 or less | b-1 | c-1 | GBL | e-1/e-4*⁴ | f-1 | g-1 | 5 | 5 | 5 |

*¹b-1/b-8 = 1/1 (mass ratio),
*²b-1/b-2 = 1/1 (mass ratio),
*³c-1/c-3 = 1/1 (mass ratio),
*⁴e-1/e-4 = 1/1 (mass ratio)

TABLE 2

| | | | | | | | | | (g) | | | |
|---|---|---|---|---|---|---|---|---|---|---|---|---|
| | (a) Polymer | | | (b) | (c) | | | | Adhesive- | | | |
| | | | Weight loss | Cross- | Photopoly- | (d) | e) Thermal | | ness- | Evaluation results | | |
| | | Acid | ratio at | linking | merization | Sol- | polymerizatior | (f) | imparting | | Heat | |
| | | value | 300° C. | agent | initiator | vent | initiator | Filler | agent | Developa- | resis- | Cura- |
| | Name | mgKOH | (%) | Name | Name | Name | Name | Name | Name | bility | tance | bility |
| Comparative | p-1 | 21 | 1 or less | b-1 | c-1 | GBL | e-1 | f-1 | — | 2 | 4 | 5 |
| Example 1 | | | | | | | | | | | | |
| Comparative | p-2 | 0 | 1 or less | b-1 | c-1 | GBL | e-1 | f-1 | — | 1 | 5 | 5 |
| Example 2 | | | | | | | | | | | | |
| Comparative | p-3 | 230 | 15 | b-1 | c-1 | GBL | e-1 | f-1 | — | 5 | 1 | 5 |
| Example 3 | | | | | | | | | | | | |
| Comparative | p-4 | 191 | 1 or less | b-1 | c-1 | GBL | e-1 | f-1 | — | 1 | 1 | 5 |
| Example 4 | | | | | | | | | | | | |
| Comparative, | a-1 | 105 | 1 or less | b-1 | c-1 | GBL | — | f-1 | g-1 | 5 | 5 | 1 |
| Example 5 | | | | | | | | | | | | |
| Comparative | a-1 | 105 | 1 or less | b-1 | c-1 | GBL | — | — | — | 5 | 5 | 1 |
| Example 6 | | | | | | | | | | | | |
| Comparative | a-1 | 105 | 1 or less | b-1 | c-1 | GBL | — | — | g-1 | 5 | 5 | 1 |
| Example 7 | | | | | | | | | | | | |

From the above results, in the photosensitive resin compositions of Examples 1 to 46, developability, heat resistance, and curability was good, and all the photosensitive resin compositions were at the practical level.

On the other hand, in the photosensitive resin compositions of Comparative Examples 1 to 7, at least one of developability, heat resistance, and curability did not satisfy the practical level.

Abbreviations described in Table 1 are as follows.

(a) Polymer
a-1 to a-10, a-1-2 to a-1-6, p-1, p-3, and p-4: a-1 to a-10, a-1-2 to a-1-6, p-1, p-3, and p-4 obtained in Synthesis Examples 1 to 18
p-2: styrene-phenyl maleimide copolymer POLYIMILEX PSX0371 (manufactured by NIPPON SHOKUBAI CO., LTD.) the following structure

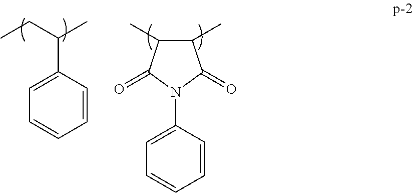

(b) Crosslinking Agent
b-1: A-9300 (manufactured by Shin-Nakamura Chemical Co., Ltd.) ethylenically unsaturated compound
b-2: A-TMPT (manufactured by Shin-Nakamura Chemical Co., Ltd.) ethylenically unsaturated compound
b-3: A-TMMT (manufactured by Shin-Nakamura Chemical Co., Ltd.) ethylenically unsaturated compound
b-4: AD-TMP (manufactured by Shin-Nakamura Chemical Co., Ltd.) ethylenically unsaturated compound
b-5: A-DPH (manufactured by Shin-Nakamura Chemical Co., Ltd.) ethylenically unsaturated compound
b-6: A-BPE-4 (manufactured by Shin-Nakamura Chemical Co., Ltd.) ethylenically unsaturated compound
b-7: 4G (manufactured by Shin-Nakamura Chemical Co., Ltd.) ethylenically unsaturated compound
b-8: BEO-60E (manufactured by New Japan Chemical Co., Ltd.) epoxy compound

(c) Photopolymerization Initiator
c-1: N-1919 (manufactured by ADEKA CORPORATION)
c-2: IRGACURE-184 (manufactured by BASF SE)
c-3: IRGACURE-OXE01 (manufactured by BASF SE)
c-4: IRGACURE-OXE02 (manufactured by BASF SE)

(d) Solvent
GBL: γ-Butyrolactone (manufactured by Wako Pure Chemical Industries, Ltd.)

(e) Thermal Polymerization Initiator
e-1: PERCUMYL D (manufactured by NOF CORPORATION, thermal radical generator, molecular weight of 270.38, 1-minute half-life period temperature of 175.2° C.)
e-2: PERBUTYL Z (manufactured by NOF CORPORATION, thermal radical generator, molecular weight of 194.23, 1-minute half-life period temperature of 166.8° C.)
e-3: PERHEXA V (manufactured by NOF CORPORATION, thermal radical generator, molecular weight of 334.46, 1-minute half-life period temperature of 172.5° C.)
e-4: PERBUTYL P (manufactured by NOF CORPORATION, thermal radical generator, molecular weight of 338.49, 1-minute half-life period temperature of 175.4° C.)
e-5: PERBUTYL D (manufactured by NOF CORPORATION, thermal radical generator, molecular weight of 146.23, 1-minute half-life period temperature of 185.9° C.)
e-6: PERHEXA 25B (manufactured by NOF CORPORATION, thermal radical generator, molecular weight of 290.45, 1-minute half-life period temperature of 179.8° C.)
e-7: PERHEXYNE 25B (manufactured by NOF CORPORATION, thermal radical generator, molecular weight of 286.42, 1-minute half-life period temperature of 194.3° C.)
e-8: PERCUMYL P (manufactured by NOF CORPORATION, thermal radical generator, molecular weight of 194.28, 1-minute half-life period temperature of 232.5° C.)
e-9: PERMENTA H (manufactured by NOF CORPORATION, thermal radical generator, molecular weight of 172.27, 1-minute half-life period temperature of 199.5° C.)
e-10: PERHEXA HC (manufactured by NOF CORPORATION, thermal radical generator, molecular weight of 316.47, 1-minute half-life period temperature of 149.2° C.)
e-11: PERCUMYL H (manufactured by NOF CORPORATION, thermal radical generator, molecular weight of 152.20, 1-minute half-life period temperature of 254.0° C.)
e-12: cyclohexyl p-toluenesulfonate (manufactured by Tokyo Chemical Industry Co., Ltd., thermal acid generator)

(f) Filler
f-1: R-972 (silica, manufactured by Nippon Aerosil Co., Ltd.)
f-2: AKP-50 (alumina, manufactured by Sumitomo Chemical Co., Ltd.)

(g) Adhesiveness-Imparting Agent
g-1: KBE-503 (3-methacryloxypropyltriethoxysilane, manufactured by Shin-Etsu Chemical Co., Ltd.)

### EXPLANATION OF REFERENCES

1: film-shaped adhesive
1a: adhesive layer pattern
2: cover film
3: resin film
6: pressure sensitive adhesive layer
7: resin film
8: semiconductor wafer
11: adhesive layer
11a: underfill layer
12, 12a, 12b: semiconductor element
13: support member for mounting a semiconductor element
14: wire
15: sealing material
16: terminal
20, 20a, 20b: semiconductor wafer provided with an adhesive layer
100, 110, 120: adhesive sheet
200, 210, 300: semiconductor device
301a to 301d: semiconductor element
301: semiconductor element laminate
302b to 302d: through-hole electrode
303a to 303e: metal bump
305: rewiring layer
310, 310a, 310b: underfill layer
315: insulating layer
320: support member for mounting a semiconductor element
320a: surface electrode

What is claimed is:

1. A photosensitive resin composition, comprising:
a polymer including a repeating unit derived from an acid group-containing maleimide;
a crosslinking agent;
a photopolymerization initiator, and
a thermal polymerization initiator.

2. The photosensitive resin composition according to claim 1,
wherein the polymer further includes a repeating unit derived from a vinyl compound.

3. The photosensitive resin composition according to claim 1, further comprising:
a solvent.

4. The photosensitive resin composition according to claim 1,
wherein the crosslinking agent is a compound having two or more groups having an ethylenically unsaturated bond.

5. The photosensitive resin composition according to claim 1,
wherein the crosslinking agent has a partial structure represented by the following formulas, and * in the formulas is a linking arm.

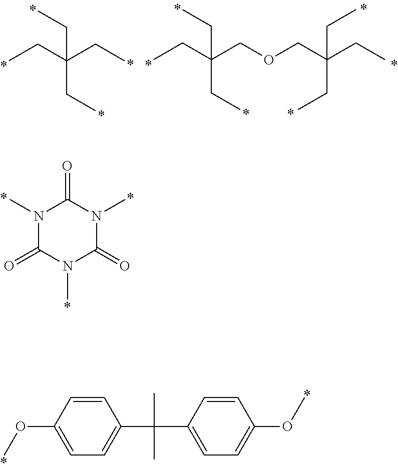

6. The photosensitive resin composition according to claim 1,
wherein the polymer is a polymer including a repeating unit represented by the following General Formula (1) and a repeating unit represented by the following General Formula (2), 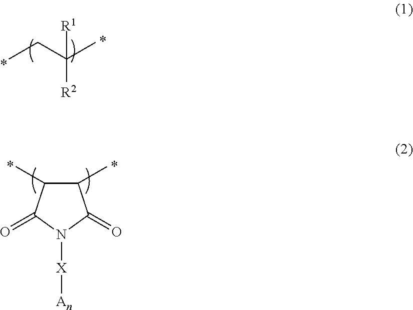
in General Formulas (1) and (2), R¹ represents a hydrogen atom or a methyl group, R² represents a hydrogen atom, an alkyl group, an alkoxy group, or an aryl group, X represents an n+1 valent linking group, A represents an acid group, n represents an integer of 1 to 10, and * represents a linking arm.

7. The photosensitive resin composition according to claim 1,
wherein the acid value of the polymer is 50 mgKOH/g or greater.

8. The photosensitive resin composition according to claim 1,
wherein the weight loss ratio of the polymer at 300° C. when the temperature is raised at a rate of 20° C./min is 5% or less.

9. The photosensitive resin composition according to claim 1, further comprising:
a filler.

10. The photosensitive resin composition according to claim 1, further comprising:
an adhesiveness-imparting agent.

11. The photosensitive resin composition according to claim 1, which is for an underfill.

12. The photosensitive resin composition according to claim 1, which is liquid.

13. The photosensitive resin composition according to claim 1, which has a sheet-shape.

14. A laminate, comprising:
a layer formed of the photosensitive resin composition according to claim 1 on a semiconductor wafer surface.

15. A laminate, comprising:
a cured product layer formed by curing the photosensitive resin composition according to claim 1 on a semiconductor wafer surface.

16. A manufacturing method for a semiconductor device, comprising:
applying the photosensitive resin composition according to claim 12 to a semiconductor wafer;
drying the photosensitive resin composition applied to the semiconductor wafer;
exposing the dried photosensitive resin composition;
developing the exposed photosensitive resin composition; and
thermal-pressing the adherend against a surface of the developed photosensitive resin composition.

17. A manufacturing method for a semiconductor device, comprising:
laminating the photosensitive resin composition according to claim 13 on a semiconductor wafer;
exposing the photosensitive resin composition laminated on the semiconductor wafer;
developing the exposed photosensitive resin composition; and
thermal-pressing the adherend against a surface of the developed photosensitive resin composition.

18. A semiconductor device manufactured by the method according to claim 16.
